(19) United States
(12) Patent Application Publication
(10) Pub. No.: US 2013/0260315 A1
(43) Pub. Date: Oct. 3, 2013

(54) RADIATION-SENSITIVE RESIN COMPOSITION, PATTERN-FORMING METHOD, POLYMER, AND COMPOUND

(71) Applicant: JSR CORPORATION, Tokyo (JP)

(72) Inventors: Mitsuo SATO, Tokyo (JP); Takehiko NARUOKA, Tokyo (JP)

(21) Appl. No.: 13/905,166

(22) Filed: May 30, 2013

Related U.S. Application Data
(63) Continuation of application No. PCT/JP2011/077715, filed on Nov. 30, 2011.

(30) Foreign Application Priority Data
Dec. 1, 2010 (JP) 2010-268872
Feb. 25, 2011 (JP) 2011-040948

(51) Int. Cl. G03F 7/004; G03F 7/20

(52) U.S. Cl. CPC G03F 7/004; G03F 7/20
USPC 430/285.1; 430/270.1; 430/325; 524/549; 524/544; 560/220; 549/420; 549/300; 549/229

(57) ABSTRACT

A radiation-sensitive resin composition includes a polymer component that includes one or more types of polymers, and a radiation-sensitive acid generator. At least one type of the polymer of the polymer component includes a first structural unit represented by a following formula (1). R¹ represents a hydrogen atom, a fluorine atom, a methyl group or a trifluoromethyl group. R² represents a linear alkyl group having 5 to 21 carbon atoms. Z represents a divalent alicyclic hydrocarbon group or an aliphatic heterocyclic group having a ring skeleton which has 4 to 20 atoms. A part or all of hydrogen atoms included in the alicyclic hydrocarbon group and the aliphatic heterocyclic group represented by Z are not substituted or substituted.

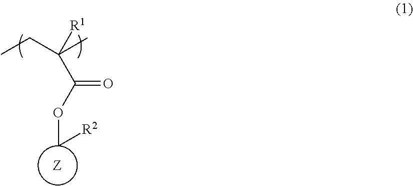

### CROSS-REFERENCE TO RELATED APPLICATIONS

The present application is a continuation application of International Application No. PCT/JP2011/077715, filed Nov. 30, 2011, which claims priority to Japanese Patent Application No. 2010-268872, filed Dec. 1, 2010, and to Japanese Patent Application No. 2011-040948, filed Feb. 25, 2011. The contents of these applications are incorporated herein by reference in their entirety.

### BACKGROUND OF THE INVENTION

1. Field of the Invention

The present invention relates to a radiation-sensitive resin composition, a pattern-forming method, a polymer, and a compound.

2. Discussion of the Background

Miniaturization of various types of electronic device structures such as semiconductor devices and liquid crystal devices has been accompanied by demands for miniaturization of resist patterns in lithography processes. Although fine resist patterns having a line width of about 90 nm can be formed using, for example, an ArF excimer laser at present, finer pattern formation is required in the future.

In such pattern formation, a chemically amplified resist has been extensively employed. This chemically amplified resist is formed from a composition containing a polymer having an acid-labile group, and a radiation-sensitive acid generator that generates an acid by irradiation with a radioactive ray. The chemically amplified resist has a property of allowing the acid-labile group to be dissociated by an acid generated upon exposure to increase solubility in an alkaline developer solution at sites exposed to light, whereby formation of a pattern is enabled.

In such a chemically amplified resist, in order to promote a dissociation reaction of the acid-labile group, and to secure sufficient solubility in an alkaline developer solution at sites exposed to light, heating after the exposure (i.e., post exposure baking (PEB)) is carried out. Although the temperature of PEB employed is typically about 100 to 180° C., diffusion of the acid to sites unexposed to light is enhanced at such a temperature of PEB, and thus lithography performances in terms of LWR (Line Width Roughness) and DOF (Depth Of Focus) may be impaired, and obtaining a favorable fine pattern may fail. Thus, lowering of a temperature of PEB would be considered in order to improve LWR, DOF and the like; however, merely lowering the temperature of PEB leads to a disadvantage that pattern formation may be difficult since dissolution in a developer solution at light-exposed sites becomes insufficient, due to a decrease in the rate of the dissociation reaction of the acid-labile group.

Accordingly, attempts of lowering of the temperature of PEB have been investigated by facilitating dissociation of the acid-labile group included in the polymer of the radiation-sensitive composition. As such a radiation-sensitive composition, for example, a positive type photopolymer composition containing a resin having an acid-labile group that has a certain acetal structure (see Japanese Unexamined Patent Application, Publication No. 2008-304902), a positive type resist composition containing a resin that includes a structural unit having a tertiary ester structure and a structural unit having a hydroxyalkyl group (see Japanese Unexamined Patent Application, Publication No. 2009-276607) and the like have been proposed.

### SUMMARY OF THE INVENTION

According to one aspect of the present invention, a radiation-sensitive resin composition includes a polymer component that includes one or more types of polymers, and a radiation-sensitive acid generator. At least one type of the polymer of the polymer component includes a first structural unit represented by a following formula (1).

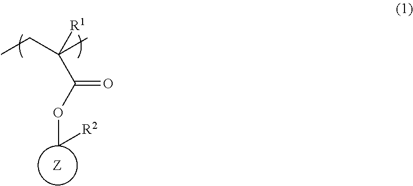

In the formula (1), R¹ represents a hydrogen atom, a fluorine atom, a methyl group or a trifluoromethyl group. R² represents a linear alkyl group having 5 to 21 carbon atoms; and Z represents a divalent alicyclic hydrocarbon group or an aliphatic heterocyclic group having a ring skeleton which has 4 to 20 atoms. A part or all of hydrogen atoms included in the alicyclic hydrocarbon group and the aliphatic heterocyclic group represented by Z are not substituted or substituted.

According to another aspect of the present invention, a pattern-forming method includes providing a resist film on a substrate using the radiation-sensitive resin composition. At least a part of the resist film is irradiated with a radioactive ray to permit exposure. The exposed resist film is heated. The heated resist film is developed.

According to further aspect of the present invention, a polymer includes a structural unit represented by a formula (1).

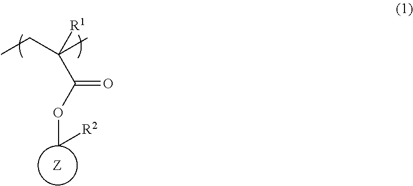

In the formula (1), R¹ represents a hydrogen atom, a fluorine atom, a methyl group or a trifluoromethyl group. R² represents a linear alkyl group having 5 to 21 carbon atoms. Z represents a divalent alicyclic hydrocarbon group or an aliphatic heterocyclic group having a ring skeleton which has 4 to 20 atoms. A part or all of hydrogen atoms included in the alicyclic hydrocarbon group and the aliphatic heterocyclic group represented by Z are not substituted or substituted.

According to further aspect of the present invention, a compound is represented by a formula (2).

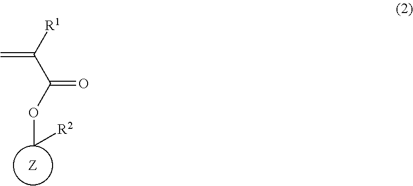

In the formula (2), R¹ represents a hydrogen atom, a fluorine atom, a methyl group or a trifluoromethyl group. R² represents a linear alkyl group having 5 to 21 carbon atoms. Z represents a divalent alicyclic hydrocarbon group or an aliphatic heterocyclic group having a ring skeleton which has 4 to 20 atoms. A part or all of hydrogen atoms included in the alicyclic hydrocarbon group and the aliphatic heterocyclic group represented by Z are not substituted or substituted.

### DESCRIPTION OF THE EMBODIMENTS

According to an embodiment of the present invention made for solving the foregoing problems, a radiation-sensitive resin composition contains:

(A) a polymer component that includes one or more types of polymers (hereinafter, may be also referred to as “(A) polymer component”); and

(B) a radiation-sensitive acid generator (hereinafter, may be also referred to as “(B) acid generator”),

at least one type of the polymer of the polymer component (A) including a structural unit (I) represented by the following formula (1):

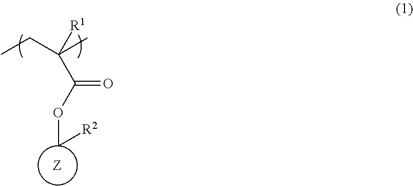

wherein, in the formula (1), R¹ represents a hydrogen atom, a fluorine atom, a methyl group or a trifluoromethyl group; R² represents a linear alkyl group having 5 to 21 carbon atoms; and Z represents a divalent alicyclic hydrocarbon group or an aliphatic heterocyclic group having a ring skeleton which has 4 to 20 atoms, wherein a part or all of hydrogen atoms included in the alicyclic hydrocarbon group and the aliphatic heterocyclic group represented by Z are not substituted or substituted.

The radiation-sensitive resin composition contains (A) a polymer component in which at least one type of the polymer includes a structural unit (I) represented by the following formula (1), and (B) an acid generator. The structural unit (I) is an acid-labile group having a structure in which a linear alkyl group having 5 or more carbon atoms bonds to a carbon atom to which an ester group bonds, in the alicyclic hydrocarbon group and aliphatic heterocyclic group. Such an acid-labile group is likely to be dissociated by an acid generated from the acid generator (B), and as a result, according to the radiation-sensitive resin composition, a dissociation reaction by an acid sufficiently proceeds even if the temperature of PEB is lowered as compared with conventionally employed temperatures. In addition, since the radiation-sensitive resin composition enables lithography performances involving LWR and DOF as a marker to be improved due to being capable of lowering the temperature of PEB, and also enables generation of bridge defects and scums to be suppressed; therefore, more favorable fine pattern can be formed. Furthermore, the radiation-sensitive resin composition is also superior in sensitivity and etching resistance.

Z in the above formula (1) preferably represents a monocyclic group. When Z represents a monocyclic group, more superior sensitivity, LWR and DOF are achieved by the radiation-sensitive resin composition, and the etching resistance is also improved. In addition, the radiation-sensitive resin composition can suppress generation of bridge defects and scums.

Z in the above formula (1) preferably represents a divalent alicyclic hydrocarbon group having 5 or more and 8 or less atoms of the ring skeleton. When Z represents the divalent alicyclic hydrocarbon group having 5 or more and 8 or less atoms of the ring skeleton, more superior sensitivity, LWR and DOF are achieved by the radiation-sensitive resin composition, and also the etching resistance is further improved. In addition, the radiation-sensitive resin composition can further suppress generation of bridges defect and scums.

R² in the above formula (1) preferably has 5 or more and 8 or less carbon atoms. In the structural unit (I), when a linear alkyl group having 5 to 8 carbon atoms bonds to a carbon atom to which an ester group bonds, the acid-labile group is more likely to be dissociated by an action of acid; therefore, the temperature of PEB can be further lowered. As a result, more superior sensitivity, LWR and DOF are achieved by the radiation-sensitive resin composition. In addition, the radiation-sensitive resin composition can further suppress generation of bridge defects and scums.

The polymer component (A) includes

(A1) base polymer, and

(A2) a fluorine-containing polymer having a content of fluorine atoms higher than that of the base polymer (A1) (hereinafter, may be also referred to as “fluorine-containing polymer (A2)”).

Since the radiation-sensitive resin composition can increase a contact angle on the surface of the resist film due to the fluorine-containing polymer (A2) serving as a water-repellent additive, it can be suitably used for liquid immersion lithography.

The base polymer (A1) preferably includes the structural unit (I). When the base polymer (A1) includes the structural unit (I), the temperature of PEB can be further lowered. As a result, more superior sensitivity, LWR and DOF are achieved by the radiation-sensitive resin composition. In addition, the radiation-sensitive resin composition can suppress generation of bridge defects and scums.

The fluorine-containing polymer (A2) preferably includes the structural unit (I). The fluorine-containing polymer (A2) as a water-repellent additive is unevenly distributed around the surface of the resist film; however, due to the fluorine-containing polymer (A2) including the structural unit (I), the dissociation reaction by an acid sufficiently proceeds also in the vicinity of the surface of the resist film. As a result, even more superior sensitivity, LWR and DOF are achieved by the radiation-sensitive resin composition. In addition, the radiation-sensitive resin composition can suppress generation of bridge defects and scums.

The base polymer (A1) preferably includes a structural unit (II) represented by the following formula (3).

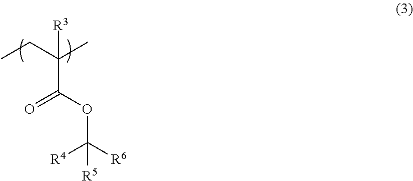

wherein, in the formula (3), R³ represents a hydrogen atom or a methyl group; R⁴ to R⁶ each independently represent an alkyl group having 1 to 4 carbon atoms or an alicyclic hydrocarbon group having 4 to 20 carbon atoms, or R⁴ represents an alkyl group having 1 to 4 carbon atoms or an alicyclic hydrocarbon group having 4 to 20 carbon atoms, and R⁵ and R⁶ taken together represent a divalent alicyclic hydrocarbon group having 4 to 20 carbon atoms together with the carbon atom to which R⁵ and R⁶ bond.

Since the base polymer (A1) includes the structural unit (II) having an acid-labile group having the above-specified structure in the radiation-sensitive resin composition, solubility in a developer solution appropriately varies upon exposure; therefore, formation of a desired pattern is enabled.

The fluorine-containing polymer (A2) preferably includes a structural unit (IV) having a fluorine atom. Since the fluorine-containing polymer (A2) that includes the structural unit (IV) can sufficiently serve as a water-repellent additive, the radiation-sensitive resin composition can further increase a contact angle on the surface of the resist film, and thus the radiation-sensitive resin composition can be suitably used for liquid immersion lithography.

According to another embodiment of the present invention, a pattern-forming method includes:

(1) a resist film-forming step of providing a resist film on a substrate using the radiation-sensitive resin composition;

(2) an exposure step of irradiating at least a part of the resist film with a radioactive ray;

(3) a heating step of heating the exposed resist film; and

(4) a development step of developing the heated resist film.

According to the pattern-forming method of the embodiment of the present invention, a favorable fine pattern can be formed.

The heating temperature in the heating step is preferably less than 100° C. According to the radiation-sensitive resin composition, since lowering of the temperature of PEB can be achieved, the diffusion length of the acid can be controlled to be shorter as a result of employing the heating temperature in the heating step after the exposure of less than 100° C., whereby a more favorable fine pattern can be formed.

According to yet another embodiment of the present invention, a polymer includes a structural unit (I) represented by the following formula (1):

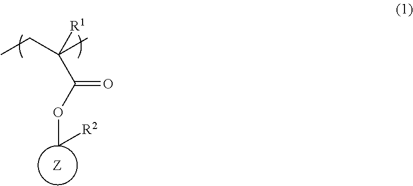

wherein, in the formula (1), R¹ represents a hydrogen atom, a fluorine atom, a methyl group or a trifluoromethyl group; R² represents a linear alkyl group having 5 to 21 carbon atoms; and Z represents a divalent alicyclic hydrocarbon group or an aliphatic heterocyclic group having a ring skeleton which has 4 to 20 atoms, wherein a part or all of hydrogen atoms included in the alicyclic hydrocarbon group and the aliphatic heterocyclic group represented by Z are not substituted or substituted.)

Since the polymer of the embodiment of the present invention has the above-specified structure, the radiation-sensitive resin composition containing the polymer enables the temperature of PEB in a resist pattern forming process to be lowered. Accordingly, diffusion of the acid is inhibited, whereby a favorable fine pattern can be formed. Thus, the polymer can be suitably used as a component for use in lithography techniques such as radiation-sensitive resin compositions.

According to yet another embodiment of the present invention, a compound is represented by the following formula (2):

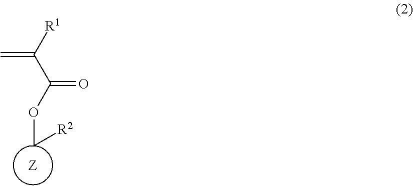

wherein, in the formula (2), R¹ represents a hydrogen atom, a fluorine atom, a methyl group or a trifluoromethyl group; R² represents a linear alkyl group having 5 to 21 carbon atoms; and Z represents a divalent alicyclic hydrocarbon group or an aliphatic heterocyclic group having a ring skeleton which has 4 to 20 atoms, wherein a part or all of hydrogen atoms included in the alicyclic hydrocarbon group and the aliphatic heterocyclic group represented by Z are not substituted or substituted.

Since the compound of the embodiment of the present invention includes the structure represented by the above formula (2), it can be suitably used as a monomer compound for incorporating the structural unit (I) in the polymer.

The “alicyclic hydrocarbon group” as referred to herein means a hydrocarbon group that is constituted with an aliphatic cyclic hydrocarbon structure and does not have an aromatic ring structure. The “aliphatic heterocyclic group” as referred to herein means a group having a ring structure similar to that of the alicyclic hydrocarbon group described above and includes, and including an atom other than carbon as the ring-constituting atom. Moreover, as referred to herein, the term “radiation” in the “radiation-sensitive resin composition” conceptionally includes a visible light ray, a ultraviolet ray, a far ultraviolet ray, an X-ray, a charged particle ray and the like are involved.

The radiation-sensitive resin composition of the embodiment of the present invention is superior in lithography performances in terms of LWR and DOF. In addition, the radiation-sensitive resin composition can suppress generation of bridge defects and scums, and is also superior in sensitivity and etching resistance even if the temperature of PEB is low; therefore, the radiation-sensitive resin composition can be suitably used in lithography steps. Moreover, in addition to the effects described above, by lowering the temperature in the heating step, reduction of energy consumption can be expected, and it is possible to realize cost reduction since a favorable pattern can be formed without further increasing the exposure dose. The embodiments will now be described in detail.

### Radiation-Sensitive Resin Composition

The radiation-sensitive resin composition of the embodiment of the present invention contains (A) a polymer component and (B) an acid generator, and within the range not leading to impairment of the effects of the embodiment of present invention, other optional component may be also contained as needed. Hereinafter, each constitutive component will be sequentially explained.

### (A) Polymer Component

The polymer component (A) in the embodiment of the present invention includes one or more types of polymers, and at least one type of the polymer of the polymer component (A) includes a structural unit (I) represented by the following formula (1). In addition, the polymer component (A) preferably includes (A1) a base polymer and (A2) a fluorine-containing polymer. In this regard, either one of the base polymer (A1) or the fluorine-containing polymer (A2) may include the structural unit (I), both the base polymer (A1) and the fluorine-containing polymer (A2) may include the structural unit (I), or a polymer other than the base polymer (A1) and the fluorine-containing polymer (A2) may include the structural unit (I).

### Structural Unit (I)

The structural unit (I) has a structure in which a linear alkyl group having 5 or more carbon atoms bonds to a carbon atom to which an ester group bonds in an alicyclic hydrocarbon group or an aliphatic heterocyclic group. The alicyclic hydrocarbon group or the aliphatic heterocyclic group serves as an acid-labile group. Such a polymer having an acid-labile group is insoluble or hardly soluble in alkali before being subjected to an action of an acid, but becomes soluble in alkali upon dissociation of the acid-labile group by an action of an acid generated from the acid generator (B), etc., contained in the radiation-sensitive resin composition. In this regard, the phrase “insoluble or hardly soluble in alkali” as referred to for polymers means a property that in the case in which a coating film having a film thickness of 100 nm produced using only such a polymer is developed in place of the resist film under conditions of development with an alkali which are employed when resist patterns are formed from the resist film that had been formed with the radiation-sensitive resin composition, no less than 50% of the initial film thickness of the film remains after the development.

In this manner, due to the acid-labile group in the polymer component (A) having a structure in which a long linear alkyl group bonds to an aliphatic ring at the above-specified position, dissociation by an acid generated from the acid generator (B) is less likely to occur. As a result, a dissociation reaction by an acid sufficiently proceeds even if the temperature of PEB is lowered than conventionally employed temperature of PEB. In addition, the radiation-sensitive resin composition enables lithography performances in terms of LWR and DOF to be improved as a result of permitting to lower the temperature of PEB. In addition, the radiation-sensitive resin composition can suppress generation of bridge defects and scums.

Although the reason for the dissociation by an acid being likely to occur due to the acid-labile group in the polymer component (A) having the above-specified structure is not necessarily clear, for example, stabilization of the carbonium ion generated upon dissociation, due to the acid-labile group having an aliphatic ring structure, as well as additionally, impairment of rigidity of the polymer component (A) to facilitate a reaction of the acid-labile group with the acid generator (B), due to the acid-labile group having a long linear alkyl group, and the like may be considered.

In the above formula (1), R² represents a hydrogen atom, a fluorine atom, a methyl group or a trifluoromethyl group; R² represents a linear alkyl group having 5 to 21 carbon atoms; and Z represents a divalent alicyclic hydrocarbon group or an aliphatic heterocyclic group having a ring skeleton which has 4 to 20 atoms, wherein a part or all of hydrogen atoms included in the alicyclic hydrocarbon group and the aliphatic heterocyclic group represented by Z are not substituted or substituted.

Examples of the linear alkyl group having 5 to 21 carbon atoms represented by R² include a n-pentyl group, a n-hexyl group, a n-heptyl group, a n-octyl group, a n-decyl group, a n-dodecyl group, a n-tetradecyl group, a n-hexadecyl group, a n-icosyl group, and the like. Of these, in light of improvement of lithography performances in terms of LWR and DOF of the radiation-sensitive resin composition, linear alkyl groups having 5 to 8 carbon atoms such as a n-pentyl group, a n-hexyl group and a n-heptyl group are preferred.

Examples of the divalent alicyclic hydrocarbon group having 4 to 20 atoms of the ring skeleton represented by Z include:

monocyclic aliphatic saturated hydrocarbon groups such as a cyclopropanediyl group, a cyclobutanediyl group, a cyclopentanediyl group, a cyclohexanediyl group, a cycloheptanediyl group, a cyclooctanediyl group, a cyclodecanediyl group and a cyclododecanediyl group;

monocyclic aliphatic unsaturated hydrocarbon groups such as a cyclobutenediyl group, a cyclopentenediyl group, a cyclohexenediyl group, a cyclodecenediyl group, a cyclododecenediyl, cyclopentadienediyl group, a cyclohexadienediyl group and a cyclodecadienediyl group;

polycyclic aliphatic saturated hydrocarbon groups such as a bicyclo[2.2.1]heptenediyl group, a bicyclo[2.2.2]octanediyl group, a tricyclo[5.2.1.0^{2,6}]decanediyl group, a tricyclo[3.3.1.1^{3,7}]decanediyl group, a tetracyclo[6.2.1.1^{3,6}.0^{2,7}]dodecanediyl group and an adamantanediyl group;

polycyclic aliphatic unsaturated hydrocarbon groups such as a bicyclo[2.2.1]heptenediyl group, a bicyclo[2.2.2]octenediyl group, a tricyclo[5.2.1.0^{2,6}]decenediyl group, a tricyclo[3.3.1.1.^{3,7}]decenediyl group and a tetracyclo[6.2.1.1^{3,6}.0^{2,7}]dodecenediyl group, and the like.

Examples of the divalent aliphatic heterocyclic group having a ring skeleton which has 4 to 20 atoms represented by Z include polycyclic aliphatic heterocyclic groups such as:

oxygen-containing groups such as an oxacyclopentanediyl group, an oxacyclohexanediyl group, an oxacycloheptanediyl group, an oxacyclooctanediyl group, an oxacyclodecanediyl group, a dioxacyclopentanediyl group, a dioxacyclohexanediyl group, a dioxacycloheptanediyl group, a dioxacyclooctanediyl group, a dioxacyclodecanediyl group, a butanolactonediyl group, a pentanolactonediyl group, a hexanolactonediyl group, a heptanolactonediyl group, an octanolactonediyl group and a decanolactonediyl group;

nitrogen-containing groups such as an azacyclopentanediyl group, an azacyclohexanediyl group, azacycloheptanediyl group, an azacyclooctanediyl group, an azacyclodecanediyl group, an a diazacyclopentanediyl group, a diazacyclohexanediyl group, a diazacycloheptanediyl group, a diazacyclooctanediyl group, a diazacyclodecanediyl group, a butanolactamdiyl group, a pentanolactamdiyl group, a hexanolactamdiyl group, a heptanolactamdiyl group, an octanolactamdiyl group and a decanolactamdiyl group;

sulfur-containing groups such as a thiacyclopentanediyl group, a thiacyclohexanediyl group, a thiacycloheptanediyl group, a thiacyclooctanediyl group, a thiacyclodecanediyl group, a dithiacyclopentanediyl group, a dithiacyclohexanediyl group, a dithiacycloheptanediyl group, a dithiacyclooctanediyl group, a dithiacyclodecanediyl group, a butanothiolactonediyl group, a pentanothiolactonediyl group, a hexanothiolactonediyl group, a heptanothiolactonediyl group, an octanothiolactonediyl group and a decanothiolactonediyl group;

monocyclic aliphatic heterocyclic groups of various hetero atom-containing groups such as an oxaazacyclopentanediyl group, an oxaazacyclohexanediyl group, an oxaazacyclooctanediyl group, an oxathiacyclopentanediyl group, an oxathiacyclohexanediyl group, an oxathiacyclooctanediyl group, a thiazacyclopentanediyl group, a thiazacyclohexanediyl group and a thiazacyclooctanediyl group;

aliphatic ring-fused lactonediyl groups such as an aliphatic ring-fused butanolactonediyl group;

hetero ring-fused cycloalkanediyl groups such as lactone ring-fused cyclopentanediyl groups, lactam ring-fused cyclopentanediyl groups, thiolactone ring-fused cyclopentanediyl group and the like; and

hetero ring-fused heterocyclic alkanediyl groups such as ring-fused 7-oxabicyclo[2.2.1]heptanediyl group, 7-azabicyclo[2.2.1]heptanediyl group, 7-thiabicyclo[2.2.1]heptanediyl group and the like fused with a lactone ring, a lactam ring, a thiolactone ring or the like.

The substituent which may be included in the alicyclic hydrocarbon group and the aliphatic heterocyclic group is exemplified by —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, or —R^{P2}—COOH (hereinafter, these substituents being also referred to collectively as “R^{S}”), wherein R^{P1} is a monovalent aliphatic chain saturated hydrocarbon group having 1 to 10 carbon atoms, a monovalent aliphatic cyclic saturated hydrocarbon group having 3 to 20 carbon atoms or a monovalent aromatic hydrocarbon group having 6 to 30 carbon atoms, wherein a part or all of hydrogen atoms included in these groups are not substituted or substituted by a fluorine atom; and R^{P2} is a single bond, a divalent aliphatic chain saturated hydrocarbon group having 1 to 10 carbon atoms, a divalent aliphatic cyclic saturated hydrocarbon group having 3 to 20 carbon atoms or a divalent aromatic hydrocarbon group having 6 to 30 carbon atoms, wherein a part or all of hydrogen atoms included in these groups are not substituted or substituted by a fluorine atom. Z may have one or more substituent(s) of one type alone, or each one or more of a plurality of types of the substituents.

Specific examples of the structural unit (I) in which Z represents a monocyclic alicyclic hydrocarbon group include a structural unit represented by the following formula (1-1), and the like.

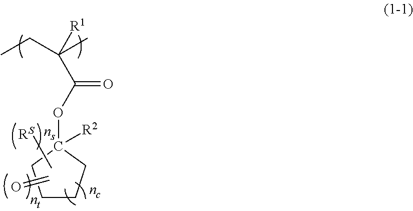

In the above formula (1-1), R¹ and R² are as defined in the above formula (1);

R^{S} is —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN or —R^{P2}—COOH, wherein
R^{P1} represents a monovalent chain saturated hydrocarbon group having 1 to 10 carbon atoms, a monovalent aliphatic cyclic saturated hydrocarbon group having 3 to 20 carbon atoms or a monovalent aromatic hydrocarbon group having 6 to 30 carbon atoms, wherein a part or all of hydrogen atoms included in these groups are not substituted or substituted by a fluorine atom, and
R^{P2} represents a single bond, a divalent chain saturated hydrocarbon group having 1 to 10 carbon atoms, a divalent aliphatic cyclic saturated hydrocarbon group having 3 to 20 carbon atoms or a divalent aromatic hydrocarbon group having 6 to 30 carbon atoms, wherein a part or all of hydrogen atoms included in these groups are not substituted or substituted by a fluorine atom,
   n_{S} is an integer of 0 to 3; and nₜ is 0 or 1.

In the above formula (1-1), n_{C} is an integer of 0 to 16.

In addition, specific examples of the structural unit (I) in which Z represents a polycyclic alicyclic hydrocarbon group include structural units represented by the following formulae (1-2) to (1-8).

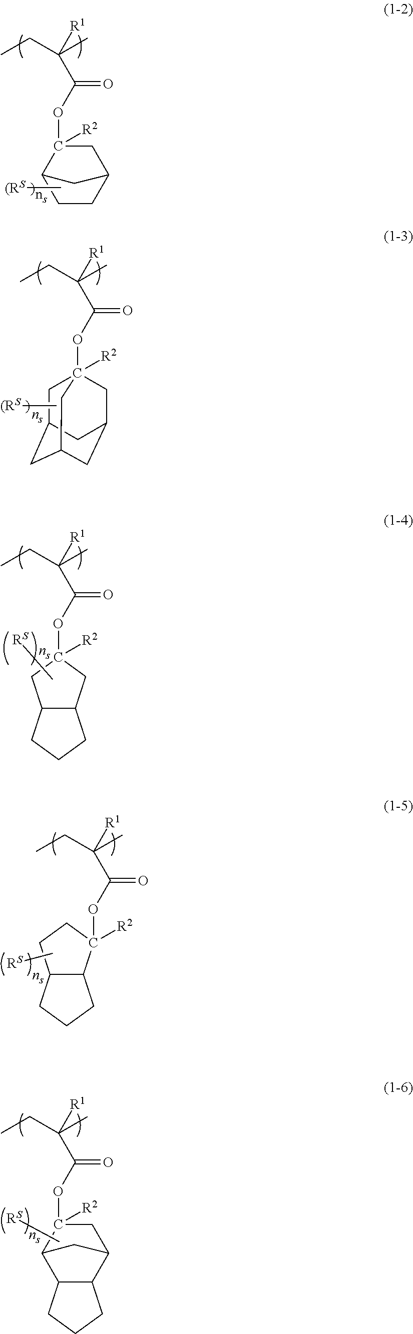

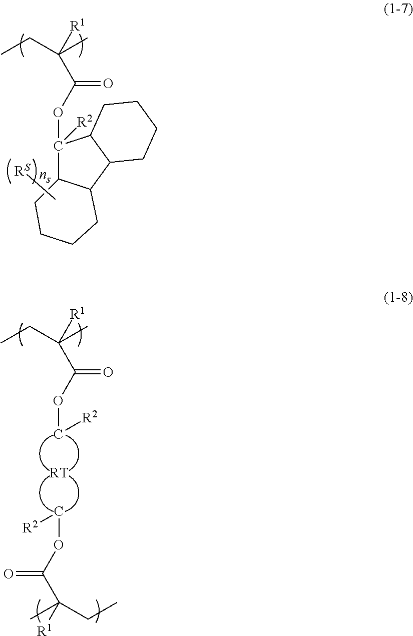

In the above formulae (1-2) to (1-8), R¹, R², R^{S} and ns are as defined in the above formula (1-1); and R^{T} represents a tetravalent aliphatic cyclic hydrocarbon group or an aliphatic heterocyclic group having 5 to 20 atoms of the polycyclic ring skeleton together with two carbon atom to which R² bonds, wherein a part or all of hydrogen atoms included in the alicyclic hydrocarbon group, and the aliphatic heterocyclic group represented by R^{T} are not substituted or substituted.

Specific examples of the structural unit (I) in which Z represents a monocyclic aliphatic heterocyclic group include a structural unit represented by the following formula (1-9), a structural unit represented by the following formula (1-10), and the like.

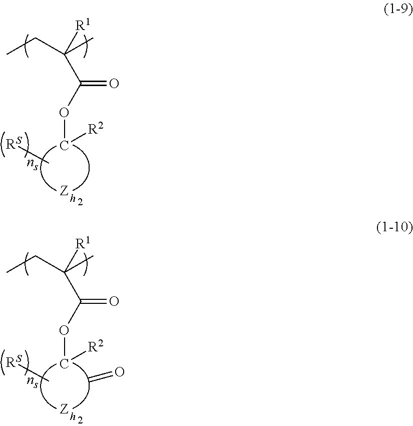

In the above formulae (1-9) and (1-10), R¹, R², R^{S} and ns are as defined in the above formula (1-1).

In the above formula (1-9), Zₕ₁ includes an oxygen atom, a sulfur atom or —NR′—, and represents a divalent aliphatic heterocyclic group having a ring skeleton which has 4 to 20 atoms together with the carbon atom to which R² bonds, wherein R′ represents a monovalent organic group.

In the above formula (1-10), Zₕ₂ includes an oxygen atom, a sulfur atom or —NR″—, and represents a divalent lactone group, a thiolactone group or a lactam group having 4 to 20 atoms of the ring skeleton together with the carbon atom and the carbonyl group to which R² bonds, wherein R″ represents a monovalent organic group.

Specific examples of the structural unit (I) in which Z represents a polycyclic aliphatic heterocyclic group include a structural unit represented by the following formula (1-11), and the like.

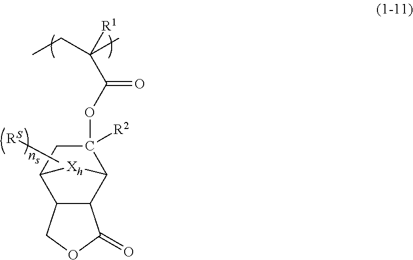

In the above formula (1-11), R¹ and R² are as defined in the above formula (1); R^{S} and nₛ are as defined in the above formula (1-1); and Xₕ represents an oxygen atom, a sulfur atom, a methylene group or an ethylene group.

The structural unit represented by the above formula (1-1) is exemplified by structural units represented by the following formulae (1-1-1) to (1-1-11), and the like.

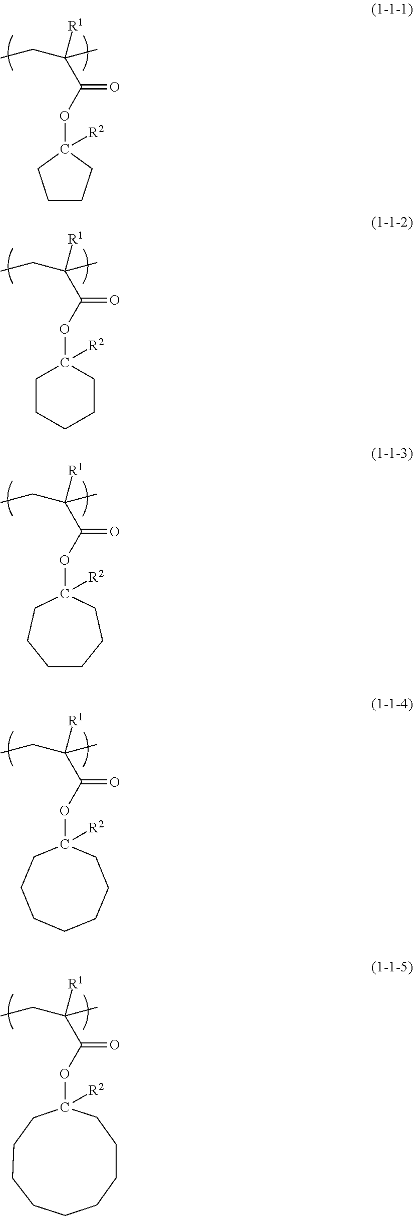

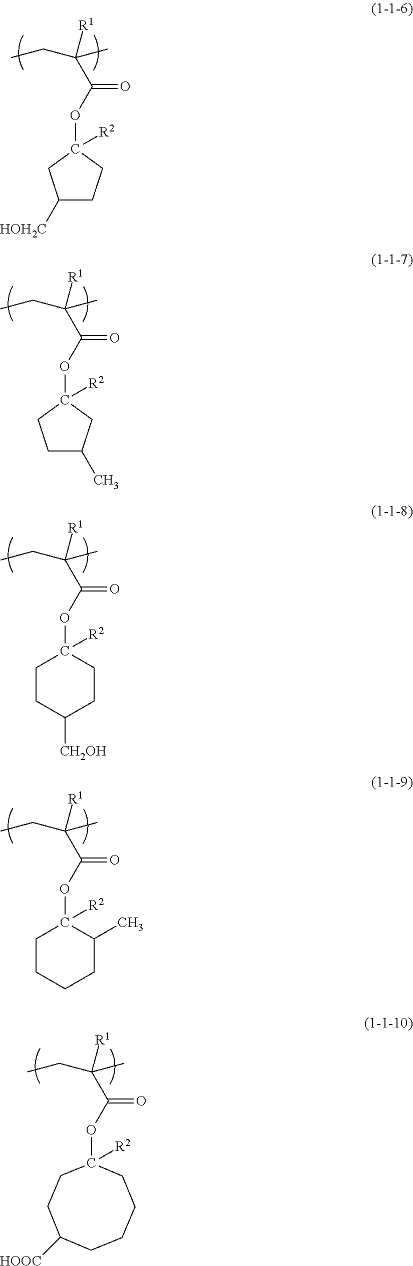

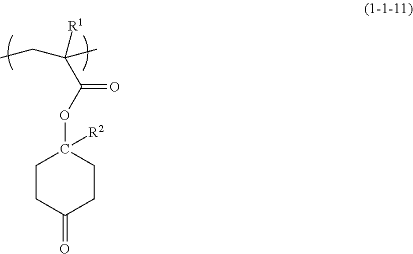

In the above formulae, R¹ and R² are as defined in the above formula (1).

The structural units represented by the above formulae (1-2) to (1-7) are exemplified by structural units represented by the following formulae (1-2-1), (1-2-2), (1-3-1), (1-3-2), (1-4-1), (1-4-2), (1-5-1), (1-5-2), (1-6-1), (1-6-2), (1-7-1) and (1-7-2), and the like.

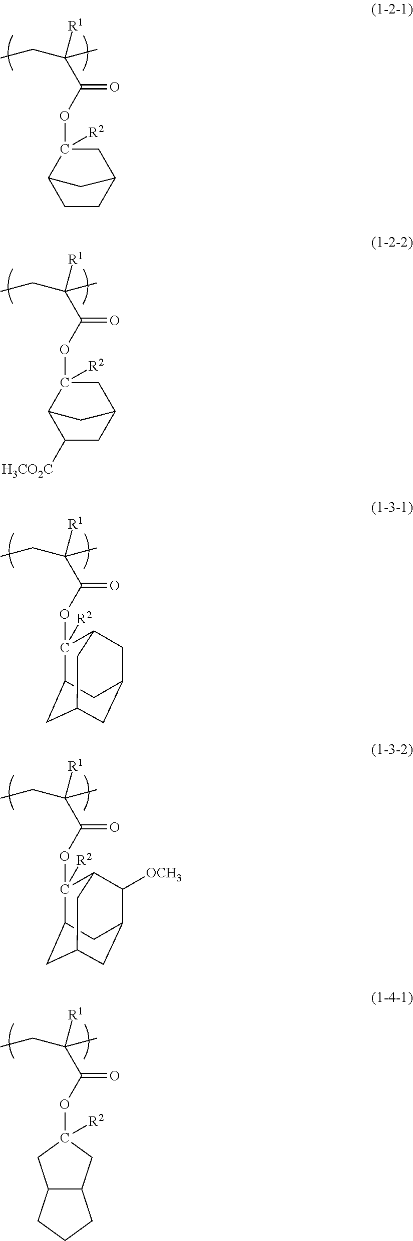

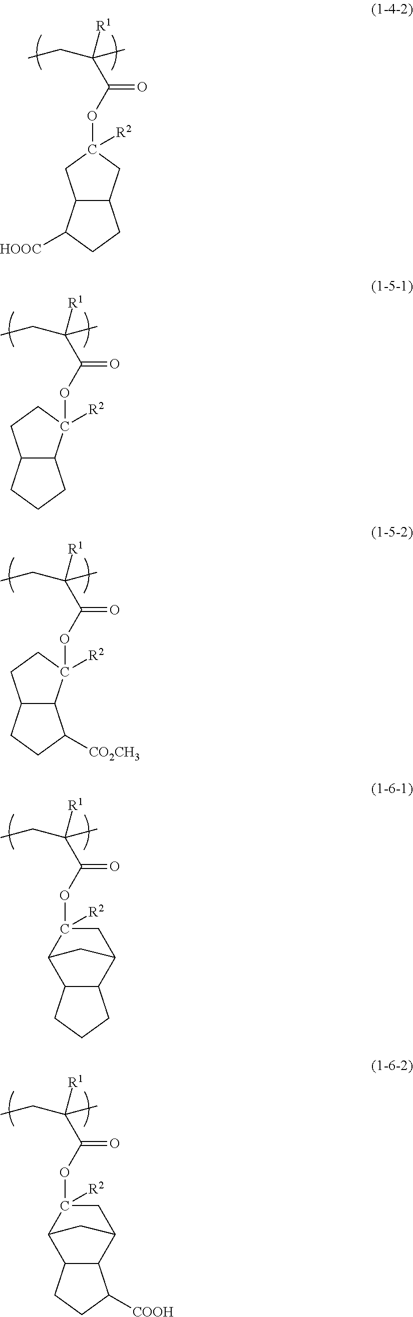

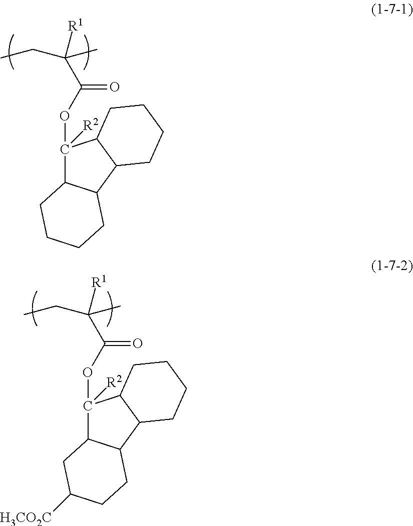

In the above formulae, R¹ and R² are as defined in the above formula (1).

The structural units represented by the above formulae (1-8) and (1-9) are exemplified by structural units represented by the following formulae (1-8-1) to (1-8-5) and (1-9-1) to (1-9-3), and the like.

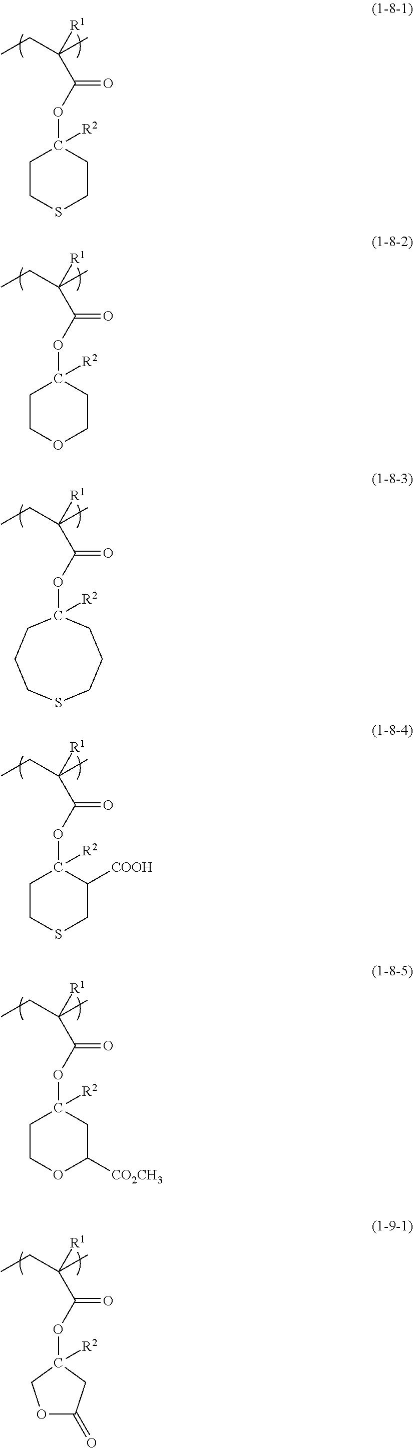

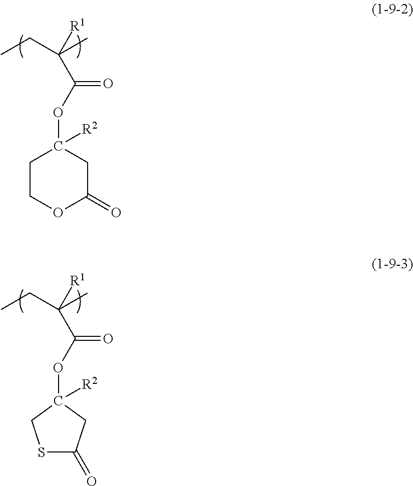

In the above formula, R¹ and R² are as defined in the above formula (1).

The structural unit represented by the above formula (1-10) is exemplified by structural units represented by the following formulae (1-10-1) to (1-10-5), and the like.

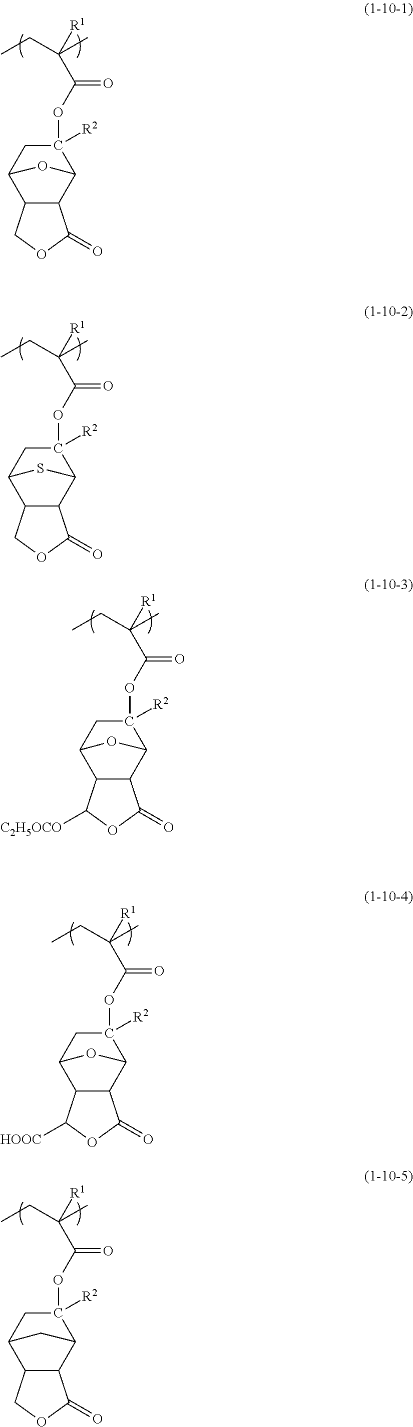

In the above formula, R¹ and R² are as defined in the above formula (1).

Among these, in light of improvement of the sensitivity, and the lithography performances in terms of LWR and DOF, and the etching resistance of the radiation-sensitive resin composition, alicyclic hydrocarbon group and aliphatic heterocyclic groups having 4 to 20 monocyclic atoms of the ring skeleton are preferred, and alicyclic hydrocarbon groups having 5 to 8 monocyclic atoms of the ring skeleton are more preferred.

Still further, in light of a diffusion length of the acid in the resist film to be shorter and improvement of the sensitivity, and the lithography performances in terms of LWR and DOF, and in light of easy synthesis of a compound that gives the structural unit, the structural units represented by the above formulae (1-1-1) to (1-1-10), respectively are preferred, and the structural units represented by the above formula (1-1-1) to (1-1-4) are more preferred of these.

The base polymer (A1) and the fluorine-containing polymer (A2) included in the polymer component (A) will be described in detail below.

### (A1) Base Polymer

The base polymer as referred to herein means a polymer having the greatest content among the all the polymers contained in the radiation-sensitive resin composition, and is preferably a polymer that includes a structural unit having an acid-labile group. With respect to the structural unit having an acid-labile group, the aforementioned structural unit (I) that serves in achieving the effects of the embodiment of present invention, and the structural unit (II) represented by the above formula (4) may be exemplified as preferred structural units. It is to be noted that the base polymer (A1) may be either (A1-1) a base polymer that includes the structural unit (I), or (A1-2) a base polymer that does not include the structural unit (I), and in light of achieving the effects of the embodiment of the present invention, the base polymer (A1-1) is preferred. The base polymer (A1-1) and the base polymer (A1-2) will be described in detail below.

### (A1-1) Base Polymer

The base polymer (A1-1) includes the structural unit (I). The base polymer (A1-1) may include the structural unit (II), a structural unit (IV) having a lactone skeleton or a cyclic carbonate skeleton and the like in addition to the structural unit (I), within a range not leading to impairment of the effects of the embodiment of the present invention. Each structural unit will be described in detail below. It is to be noted that the base polymer (A1-1) may be used together with (A2-1) a fluorine-containing polymer, or together with the (A2-2) a fluorine-containing polymer described later.

### Structural Unit (I)

The content of the structural unit (I) in the base polymer (A1-1) is preferably 1 to 90 mol %, more preferably 5 to 70 mol %, and still more preferably 15 to 50 mol %. When the content falls within such a range, the sensitivity, and the lithography performances in terms of LWR and DOF, and the etching resistance of the radiation-sensitive resin composition can be further improved. It is to be noted that the base polymer (A1-1) may include one, or two or more types of the structural unit (I).

### Structural Unit (II)

The structural unit (II) is represented by the above formula (3).

In the formula (3), R³ represents a hydrogen atom, a fluorine atom, a methyl group or a trifluoromethyl group; R⁴ to R⁶ each independently represent an alkyl group having 1 to 4 carbon atoms or an alicyclic hydrocarbon group having 4 to 20 carbon atoms, or R⁴ represents an alkyl group having 1 to 4 carbon atoms or an alicyclic hydrocarbon group having 4 to 20 carbon atoms, and R⁵ and R⁶ taken together represent a divalent alicyclic hydrocarbon group having 4 to 20 carbon atoms together with the carbon atom to which R⁵ and R⁶ bond.

Examples of the alkyl group having 1 to 4 carbon atoms include a methyl group, an ethyl group, a n-propyl group, an i-propyl group, a n-butyl group, a 2-methylpropyl group, a 1-methylpropyl group, a t-butyl group, and the like.

The alicyclic hydrocarbon group having 4 to 20 carbon atoms, or the alicyclic hydrocarbon group having 4 to 20 carbon atoms optionally taken together represented by R⁵ and R⁶ together with the carbon atom which R⁵ and R⁶ bond is exemplified by a polycyclic alicyclic hydrocarbon group having a bridged skeleton such as an adamantane skeleton or a norbornane skeleton; and a monocyclic alicyclic hydrocarbon group having a cycloalkane skeleton such as cyclopentane or cyclohexane. In addition, these groups may be substituted with, for example, one or more types of linear, branched or cyclic alkyl groups having 1 to 10 carbon atoms.

Preferred structural unit (II) is represented by the following formulae.

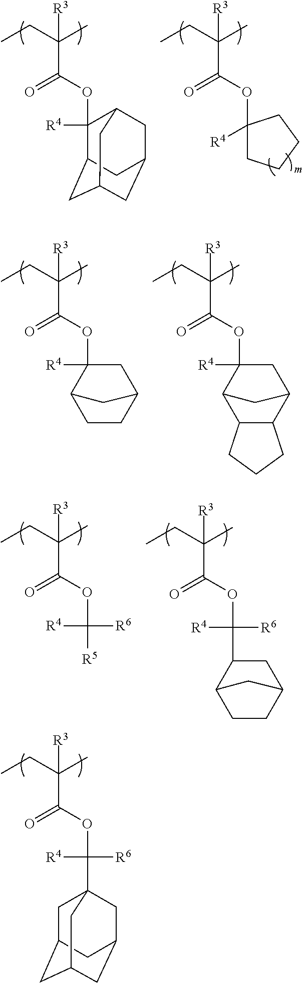

In the above formula, R³ to R⁶ are as defined in the above formula (3), wherein R⁴, R⁵ and R⁶ represent an identical group; and m is an integer of 1 to 6.

Of these, structural units represented by the following formulae (3-1) to (3-18) are more preferred, and structural units represented by the formulae (3-3), (3-4), (3-11) and (3-12) are particularly preferred.

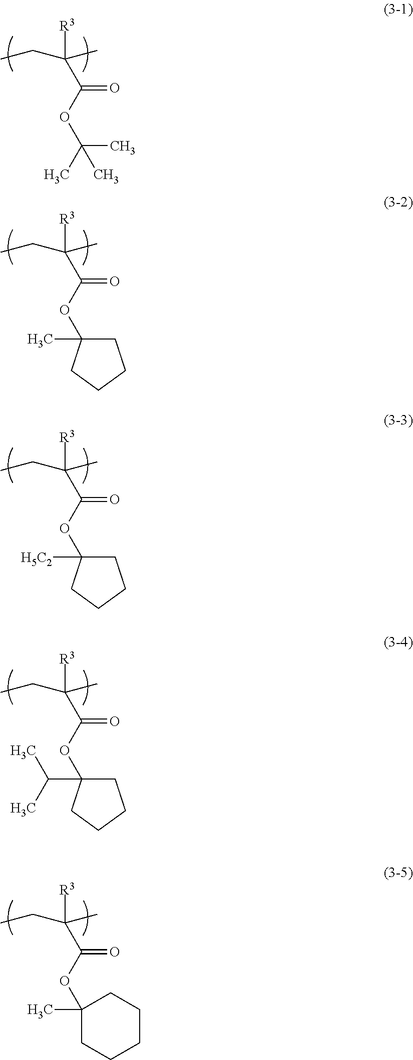

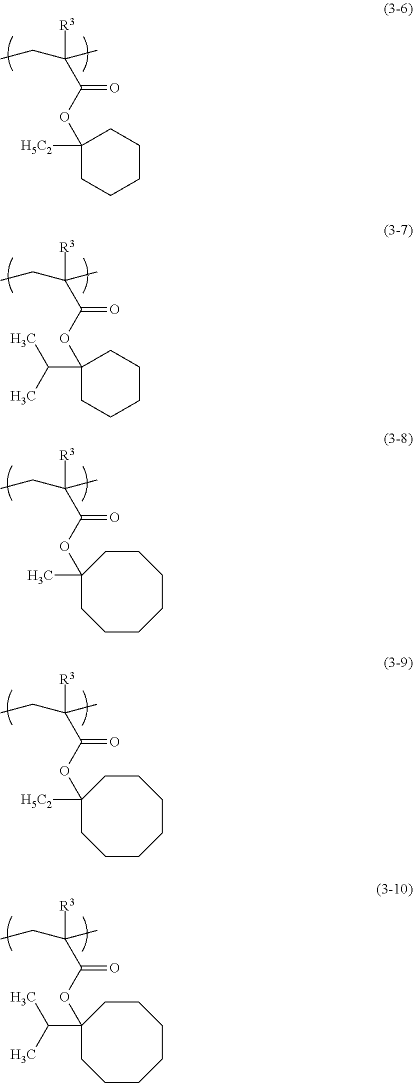

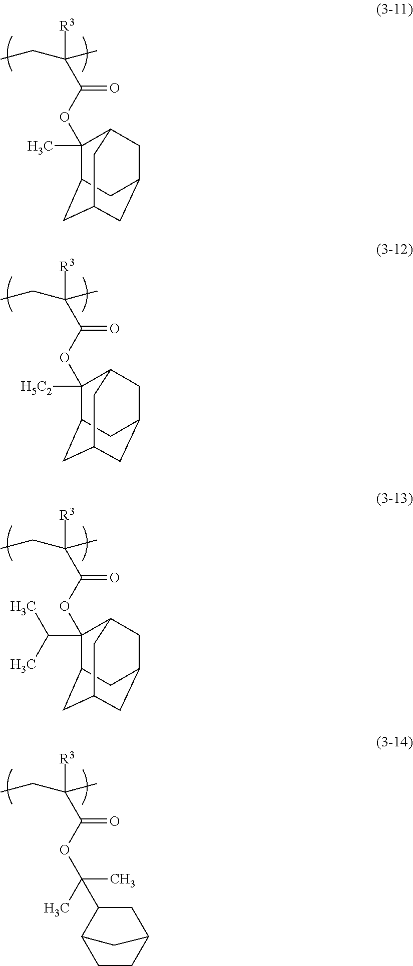

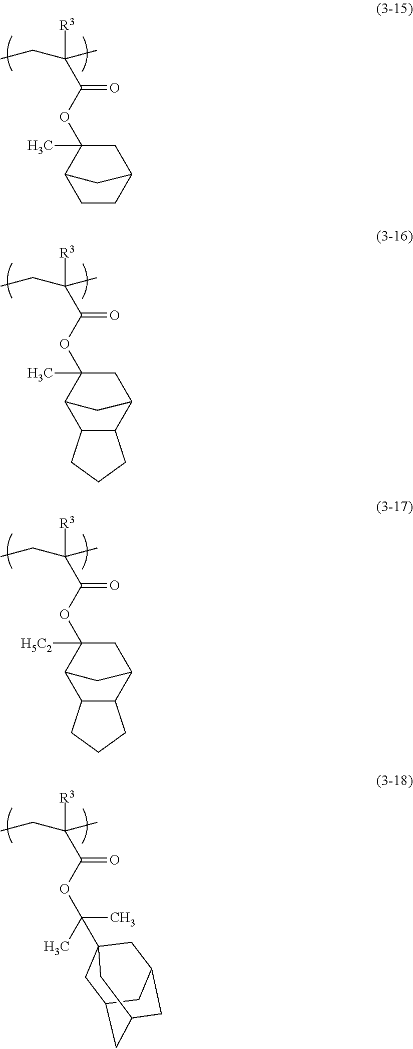

In the above formula, R³ is as defined in the above formula (3).

The proportion of the structural unit (II) in the base polymer (A1-1) with respect to the entire structural units constituting the base polymer (A1-1) is preferably 5 mol % to 80 mol %, more preferably 10 mol % to 80 mol %, and still more preferably 20 mol % to 70 mol %. When the proportion of the structural unit (II) included exceeds 80 mol %, the sensitivity, and the lithography performances in terms of LWR and DOF, and the etching resistance of the radiation-sensitive resin composition may be deteriorated. To the contrary, when the proportion is less than 5 mol %, the solubility in an alkali at light-exposed sites may be insufficient, whereby obtaining a favorable pattern may fail. It is to be noted that the base polymer (A1-1) may include one, or two or more types of the structural unit (II).

Examples of a monomer that gives the structural unit (II) include (meth)acrylic acid-bicyclo[2.2.1]hept-2-yl ester, (meth)acrylic acid-bicyclo[2.2.2]oct-2-yl ester, (meth)acrylic acid-tricyclo[5.2.1.0^{2,6}]dec-7-yl ester, (meth)acrylic acid-tricyclo[3.3.1.1^{3,7}]dec-1-yl ester, (meth)acrylic acid-tricyclo[3.3.1.1^{3,7}]dec-2-yl ester, and the like.

### Structural Unit (III)

The base polymer (A1-1) may further include a structural unit (III) having a lactone skeleton or a cyclic carbonate skeleton. When the structural unit (III) is included, the sensitivity, and the lithography performances in terms of LWR and DOF of the resulting pattern can be further improved.

Examples of the structural unit (III) are represented by the following formulae.

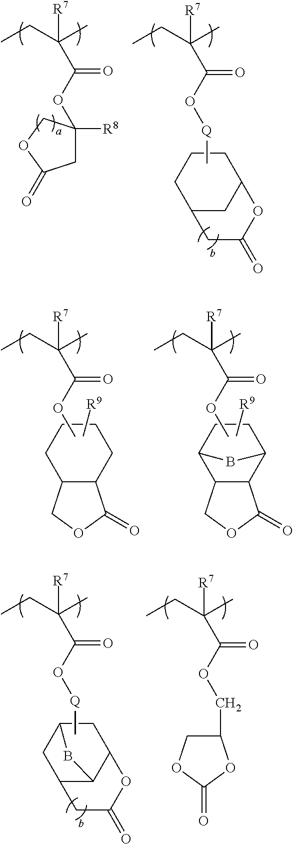

In the above formula, R⁷ represents a hydrogen atom, a fluorine atom, a methyl group or a trifluoromethyl group; R⁸ represents a hydrogen atom or a methyl group; R⁹ represents a hydrogen atom or a methoxy group; Q represents a single bond or a methylene group; B represents a methylene group or an oxygen atom; a and b are each 0 or 1.

Preferred structural unit (III) is represented by the following formulae.

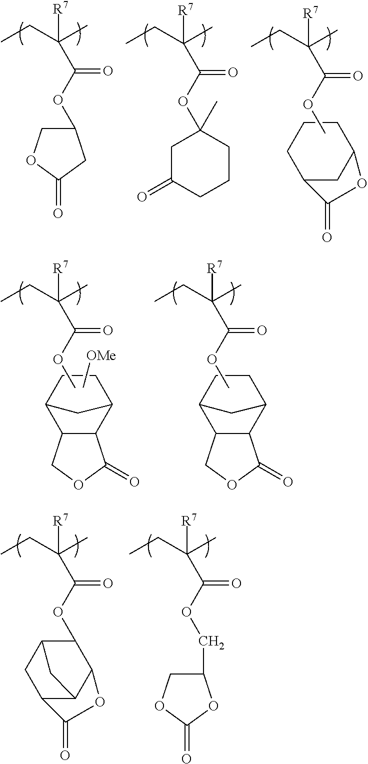

In the above formula, R⁷ represents a hydrogen atom, a fluorine atom, a methyl group or a trifluoromethyl group.

The proportion of the structural unit (III) in the base polymer (A1-1) with respect to the entire structural units constituting the base polymer (A1-1) is preferably 0 mol % to 70 mol %, and more preferably 10 mol % to 60 mol %. When the content falls within such a range, the sensitivity, and the lithography performances in terms of LWR and DOF can be improved. On the other hand, when the content exceeds 70 mol %, the sensitivity, and the lithography performances in terms of LWR and DOF may be deteriorated. It is to be noted that the base polymer (A1-1) may include one, or two or more types of the structural unit (III).

A monomer that gives the structural unit (III) is exemplified by monomers described in the pamphlet of PCT International Publication No. 2007/116664.

### Synthesis Method of Polymer (A1-1)

The polymer (A1-1) may be synthesized according to a common procedure such as radical polymerization. The polymer (A) is preferably synthesized according to a method such as, e.g.:

a method in which a solution containing a monomer and a radical initiator is added dropwise to a solution containing a reaction solvent or a monomer to permit a polymerization reaction; or

a method in which a solution containing a monomer, and a solution containing a radical initiator are each separately added dropwise to a solution containing a reaction solvent or a monomer to permit a polymerization reaction;

a method in which a plurality of solutions each containing a monomer, and a solution containing a radical initiator are each separately added dropwise to a solution containing a reaction solvent or a monomer to permit a polymerization reaction.

It is to be noted that when the reaction is allowed by adding a monomer solution dropwise to a monomer solution, the amount of the monomer in the monomer solution added is preferably no less than 30 mol %, more preferably no less than 50 mol %, and particularly preferably no less than 70 mol % with respect to the total amount of the monomers used in the polymerization. It should be noted that the synthesis method of the monomer that is the compound of the embodiment of the present invention represented by the above formula (2) is described later.

The reaction temperature in these methods may be determined ad libitum depending of the type of the initiator species. The reaction temperature is usually 30° C. to 180° C., preferably 40° C. to 160° C., and more preferably 50° C. to 140° C. The time period for the dropwise addition may vary depending on the conditions such as the reaction temperature, the type of the initiator and the monomer to be reacted, but is usually 30 min to 8 hrs, preferably 45 min to 6 hrs, and more preferably 1 hour to 5 hrs. Further, the total reaction time period including the time period for dropwise addition may also vary depending on the conditions similarly to the time period for the dropwise addition, and is typically 30 min to 8 hrs, preferably 45 min to 7 hrs, and more preferably 1 hour to 6 hrs.

The radical initiator for use in the polymerization is exemplified by azobisisobutyronitrile (AIBN), 2,2′-azobis(4-methoxy-2,4-dimethyl valeronitrile), 2,2′-azobis(2-cyclopropyl propionitrile), 2,2′-azobis(2,4-dimethyl valeronitrile), and the like. These initiators may be used either alone or as a mixture of two or more thereof.

The solvent for polymerization is not limited as long as it is any solvent other than solvents that inhibit the polymerization (nitrobenzene having a polymerization inhibitory effect, mercapto compounds having a chain transfer effect, etc.), and which is capable of dissolving the monomer.

Examples of the solvent for use in the polymerization include:

alkanes such as n-pentane, n-hexane, n-heptane, n-octane, n-nonane and n-decane;

cycloalkanes such as cyclohexane, cycloheptane, cyclooctane, decalin and norbornane;

aromatic hydrocarbons such as benzene, toluene, xylene, ethylbenzene and cumene;

halogenated hydrocarbons such as chlorobutanes, bromohexanes, dichloroethanes, hexamethylenedibromide and chlorobenzene;

saturated carboxylate esters such as ethyl acetate, n-butyl acetate, i-butyl acetate and methyl propionate;

ketones such as acetone, 2-butanone, 4-methyl-2-pentanone and 2-heptanone;

ethers such as tetrahydrofuran, dimethoxy ethanes and diethoxyethanes;

alcohols such as methanol, ethanol, 1-propanol, 2-propanol and 4-methyl-2-pentanol, and the like. These solvents may be used either alone, or two or more types thereof may be used in combination.

The resin obtained by the polymerization reaction may be recovered preferably by a reprecipitation technique. More specifically, after the polymerization reaction is completed, the polymerization mixture is charged into a solvent for reprecipitation, whereby a target resin is recovered in the form of powder. As the reprecipitation solvent, an alcohol, an alkane or the like may be used either alone or as a mixture of two or more thereof. Alternatively to the reprecipitation technique, liquid separating operation, column operation, ultrafiltration operation or the like may be employed to recover the resin through eliminating low molecular components such as monomers and oligomers.

The polystyrene equivalent weight average molecular weight (Mw) of the base polymer (A1-1) as determined by gel permeation chromatography (GPC) is not particularly limited, and preferably no less than 1,000 and no greater than 100,000, more preferably no less than 2,000 and no greater than 50,000, and particularly preferably no less than 3,000 and no greater than 20,000. When the Mw falls within the above range, the radiation-sensitive resin composition may be superior in sensitivity, lithography performances in terms of LWR and DOF, and etching resistance.

Also, the ratio (Mw/Mn) of Mw to the polystyrene equivalent number average molecular weight (Mn) as determined by GPC of the polymer (A1-1) is typically 1 or greater and 5 or less, preferably 1 or greater and 3 or less, and more preferably 1 or greater and 2 or less. When the ratio Mw/Mn falls within such a range, the radiation-sensitive resin composition may be superior in sensitivity, lithography performances in terms of LWR and DOF, and etching resistance.

It is to be noted that Mw and Mn as referred to herein mean values determined by GPC using GPC columns manufactured by Tosoh Corporation (“G2000HXL”×2, “G3000HXL”×1 and “G4000HXL”×1), under conditions involving a flow rate of 1.0 mL/min, an elution solvent of tetrahydrofuran and a column temperature of 40° C., and with monodisperse polystyrene as a standard.

### (A1-2) Base Polymer

The base polymer (A1-2) is a base polymer which does not include the structural unit (I). The base polymer (A1-2) is preferably used in combination with the fluorine-containing polymer (A2-1) that includes the structural unit (I) described later.

The base polymer (A1-2) preferably includes the structural unit (II) as the structural unit having an acid-labile group. The base polymer (A1-2) may include a structural unit (III) having a lactone skeleton or a cyclic carbonate skeleton, and/or a structural unit (IV) having an alicyclic structure, in addition to the structural unit (II). It is to be noted that the structural unit (II) and the structural unit (III) are exemplified by structural units similar to the structural unit (II) and the structural unit (III) of the base polymer (A1-1), respectively.

In the base polymer (A1-2), the content of the structural unit (II) is preferably 20 mol % to 60 mol % with respect to the total amount of the entire structural units constituting the base polymer (A1-2). It is to be noted that the base polymer (A1-2) may include one, or two or more types of the structural unit (II).

In the base polymer (A1-2), the content of the structural unit (III) is preferably 30 mol % to 60 mol % with respect to the total amount of the entire structural units constituting the base polymer (A1-2). It is to be noted that the base polymer (A1-2) may include one, or two or more types of the structural unit (III).

As the structural unit (IV), for example a structural unit represented by the following formula (4), and the like may be exemplified.

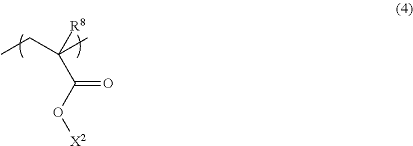

In the formula (4), R⁸ represents a hydrogen atom, a fluorine atom, a methyl group or a trifluoromethyl group; and X² represents an alicyclic hydrocarbon group having 4 to 20 carbon atoms.

Examples of the alicyclic hydrocarbon group having 4 to 20 carbon atoms include cyclobutane, cyclopentane, cyclohexane, bicyclo[2.2.1]heptane, bicyclo[2.2.2]octane, tricyclo[5.2.1.0^{2,6}]decane, tetracyclo[6.2.1.1^{3,6}.0^{2,7}]dodecane, tricyclo[3.3.1.1^{3,7}]decane, and the like. These alicyclic hydrocarbon groups having 4 to 20 carbon atoms do not have or have a substituent. Examples of the substituent include linear, branched or cyclic alkyl groups having 1 to 4 carbon atoms such as a methyl group, an ethyl group, a n-propyl group, an i-propyl group, a n-butyl group, a 2-methylpropyl group, a 1-methylpropyl group and a t-butyl group; a hydroxyl group, a cyano group, a hydroxyalkyl group having 1 to 10 carbon atoms, a carboxyl group, an oxygen atom, and the like.

Examples of the monomer that gives the structural unit having an alicyclic structure include (meth)acrylic acid-bicyclo[2.2.1]hept-2-yl ester, (meth)acrylic acid-bicyclo[2.2.2]oct-2-yl ester, (meth)acrylic acid-tricyclo[5.2.1.0^{2,6}]dec-7-yl ester, (meth)acrylic acid-tricyclo[3.3.1.1^{3,7}]dec-1-yl ester, (meth)acrylic acid-tricyclo[3.3.1.1^{3,7}]dec-2-yl ester, and the like.

### Synthesis Method of Base Polymer (A1-2)

The base polymer (A1-2) may be produced by, for example, polymerizing a monomer corresponding to each predetermined structural unit using a radical polymerization initiator in an appropriate solvent.

Examples of the solvent for use in the polymerization include those exemplified in the synthesis method of the base polymer (A1-1).

The reaction temperature in the polymerization is typically 40° C. to 150° C., and preferably 50° C. to 120° C. The reaction time period is typically 1 hr to 48 hrs, and preferably 1 hr to 24 hrs.

Mw of the base polymer (A1-2) in accordance with a GPC technique is preferably 1,000 to 100,000, more preferably 1,000 to 50,000, and particularly preferably 1,000 to 30,000. When Mw of the base polymer (A1-2) falls within the above range, solubility in a solvent of a resist sufficient for use as a resist is attained, and favorable resistance to dry etching and a favorable cross-sectional shape of the resist pattern may be obtained.

The ratio (Mw/Mn) of Mw to Mn of the base polymer (A1-2) is typically 1 to 3, and preferably 1 to 2.

### (A2) Fluorine-Containing Polymer

The fluorine-containing polymer (A2) has a content of fluorine atoms higher than that of the base polymer (A1). Since the fluorine-containing polymer (A2) serves as a water-repellent additive to be capable of increasing a contact angle on the surface of the resist film, the radiation-sensitive resin composition can be suitably used in liquid immersion lithography by containing the fluorine-containing polymer (A2). The fluorine-containing polymer (A2) may be either (A2-1) a fluorine-containing polymer that includes the structural unit (I), or (A2-2) a fluorine-containing polymer that does not include the structural unit (I), and in light of achieving the effects of the embodiment of the present invention, the fluorine-containing polymer (A2-1) is preferred. The fluorine-containing polymer (A2-1) and the fluorine-containing polymer (A2-2) will be described in detail below.

### (A2-1) Fluorine-Containing Polymer

The fluorine-containing polymer (A2-1) includes the structural unit (I) represented by the above formula (1). When the fluorine-containing polymer (A2) included in the polymer component (A) is the fluorine-containing polymer (A2-1), the radiation-sensitive resin composition can suppress generation of bridge defects and scums even if the temperature of PEB is low, and a formation of a fine pattern that is superior in performances in terms of LWR and favorable is enabled. It is to be noted that in the case where the fluorine-containing polymer (A2) is the fluorine-containing polymer (A2-1), either the base polymer (A1-1) or the base polymer (A1-2) may be used as the base polymer.

It is preferred that the fluorine-containing polymer (A2-1) further includes a structural unit (V) having a fluorine atom. In addition thereto, the structural unit (II) having the acid-labile group represented by the above formula (4), the structural unit (III) having a lactone skeleton or a cyclic carbonate skeleton, the structural unit (IV) having an alicyclic structure may be also included. Each structural unit will be described in detail below.

### Structural Unit (I)

Due to having the structural unit (I), the fluorine-containing polymer (A2-1) is less likely to be accompanied by occurrence of dissociation by an acid generated from the acid generator (B). As a result, a dissociation reaction by an acid sufficiently proceeds even if the temperature of PEB is lowered as compared with conventionally employed temperatures. Accordingly, generation of bridge defects and scums can be suppressed. In addition, due to being capable of lowering the temperature of PEB, lithography performances in terms of LWR can be improved. It is to be noted that a description in connection with the structural unit (I) in the base polymer (A1-1) may be applied to the structural unit (I).

The content of the structural unit (I) in the fluorine-containing polymer (A2-1) is preferably 1 to 60 mol %, more preferably 3 to 40 mol %, and still more preferably 5 to 35 mol %. When the content falls within such a range, generation of bridge defects and scums of a pattern formed from the radiation-sensitive resin composition can be suppressed, whereby LWR can be further reduced. It is to be noted that the polymer (A2-1) may include one, or two or more types of the structural unit (I).

### Structural Unit (II)

The fluorine-containing polymer (A2-1) may include a structural unit (II) represented by the above formula (4). It is to be noted that a description in connection with the structural unit (II) in the base polymer (A1-1) may be applied to the structural unit (II).

The proportion of the structural unit (II) in the fluorine-containing polymer (A2-1) is preferably 0 mol % to 80 mol %, more preferably 2 mol % to 80 mol %, and still more preferably 5 mol % to 50 mol %. When the proportion of the structural unit (II) included exceeds 80 mol %, an increase of bridge defects and LWR of the resulting pattern may occur. Note that the fluorine-containing polymer (A2-1) may include one, or two or more types of the structural unit (II).

### Structural Unit (III)

The fluorine-containing polymer (A2-1) may further include a structural unit (III) having a lactone skeleton or a cyclic carbonate skeleton. Due to including the structural unit (III), adhesiveness of the radiation-sensitive resin composition to a substrate and the like is improved. It is to be noted that a description in connection with the structural unit (III) in the base polymer (A1-1) may be applied to the structural unit (III).

### Structural Unit (IV)

The fluorine-containing polymer (A2-1) may include the structural unit (IV) having an alicyclic structure. It is to be noted that a description in connection with the structural unit (IV) in the base polymer (A1-1) may be applied to the structural unit (IV).

### Structural Unit (V)

The fluorine-containing polymer (A2-1) may include the structural unit (V) having a fluorine atom.

In this regard, modes of inclusion of a fluorine atom in the fluorine-containing polymer (A2-1) may involve:

a structure in which a fluorinated alkyl group bonds to its main chain;

a structure in which a fluorinated alkyl group bonds to its side chain; and

a structure in which a fluorinated alkyl group bonds to its main chain and a side chain.

Examples of the monomer that gives the structure in which a fluorinated alkyl group bonds to its main chain include α-trifluoromethyl acrylate compounds, β-trifluoromethyl acrylate compounds, α,β-trifluoromethyl acrylate compounds, compounds derived by substituting hydrogen atom of one or more types of vinyl moieties by a fluorinated alkyl group such as a trifluoromethyl group, and the like.

Examples of the monomer that gives the structure in which a fluorinated alkyl group bonds to its side chain include alicyclic olefin compounds such as norbornene having fluorinated alkyl group and/or a derivative thereof as a side chain, ester compounds of acrylic acid or methacrylic acid having a fluorinated alkyl group and/or a derivative thereof as a side chain, olefins having a fluorinated alkyl group and/or a derivative thereof as one or more types of side chain (a site excluding a double bond), and the like.

Examples of the monomer that gives the structure in which a fluorinated alkyl group bonds to its main chain and side chain include ester compounds of α-trifluoromethyl acrylic acid, β-trifluoromethyl acrylic acid, α,β-trifluoromethyl acrylic acid or the like with a fluorinated alkyl group and/or a derivative thereof as a side chain, compounds derived by substituting hydrogen of one or more types of vinyl moieties by a fluorinated alkyl group and substituting a side chain of the compound with a fluorinated alkyl group and/or a derivative thereof; alicyclic olefin compounds derived by substituting hydrogen bonded to one or more types of double bonds by a fluorinated alkyl group, etc., and having a fluorinated alkyl group and/or a derivative thereof as a side chain; and the like. The alicyclic olefin compound as referred to herein means a compound that includes a double bond in a part of its ring.

The fluorine-containing polymer (A2-1) may include as the structural unit (V), a structural unit (V-1) represented by the following formula (5) and/or a structural unit (V-2) represented by the formula (6).

### Structural Unit (V-1)

The structural unit (V-1) is represented by the following formula (5).

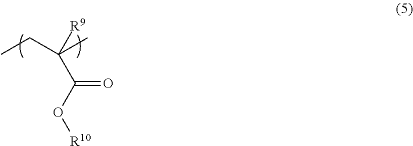

In the above formula (5), R⁹ represents a hydrogen atom, a fluorine atom, a methyl group or a trifluoromethyl group; R¹⁰ represents a linear or branched alkyl group having 1 to 6 carbon atoms and having a fluorine atom, or a monovalent alicyclic hydrocarbon group having 4 to 20 carbon atoms and having a fluorine atom, wherein, a part or all of hydrogen atoms of the alkyl group and the alicyclic hydrocarbon group represented by R¹⁰ are not substituted or substituted.

Examples of the linear or branched alkyl group having 1 to 6 carbon atoms include a methyl group, an ethyl group, a propyl group, a butyl group, and the like.

Examples of the monovalent alicyclic hydrocarbon group having 4 to 20 carbon atoms include a cyclopentyl group, a cyclopentylpropyl group, a cyclohexyl group, a cyclohexylmethyl group, a cycloheptyl group, a cyclooctyl group, a cyclooctylmethyl group, and the like.

Examples of the monomer that gives the structural unit (II-1) include trifluoromethyl(meth)acrylate, 2,2,2-trifluoroethyl(meth)acrylate, perfluoroethyl(meth)acrylate, perfluoro n-propyl(meth)acrylate, perfluoro i-propyl(meth)acrylate, perfluoro n-butyl(meth)acrylate, perfluoro i-butyl(meth)acrylate, perfluoro t-butyl(meth)acrylate, perfluorocyclohexyl(meth)acrylate, 2-(1,1,1,3,3,3-hexafluoro)propyl(meth)acrylate, 1-(2,2,3,3,4,4,5,5-octafluoro)pentyl(meth)acrylate, 1-(2,2,3,3,4,4,5,5-octafluoro)hexyl(meth)acrylate, perfluorocyclohexylmethyl(meth)acrylate, 1-(2,2,3,3,3-pentafluoro)propyl(meth)acrylate, 1-(2,2,3,3,4,4,4-heptafluoro)penta(meth)acrylate, 1-(3,3,4,4,5,5,6,6,7,7,8,8,9,9,10,10,10-heptadecafluoro)decyl(meth)acrylate, 1-(5-trifluoromethyl-3,3,4,4,5,6,6,6-octafluoro)hexyl(meth)acrylate, and the like.

The structural unit (V-1) is exemplified by structural units represented by the following formulae (5-1) and (5-2).

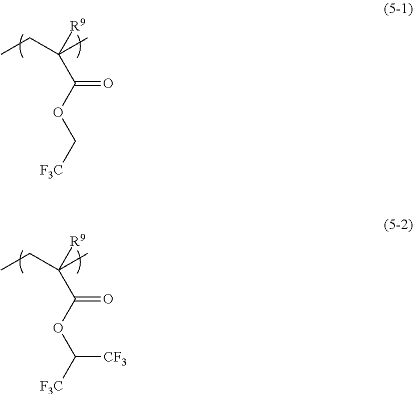

wherein, in the formulae (5-1) and (5-2), R⁹ is as defined in the above formula (5).

In the fluorine-containing polymer (A2-1), the content of the structural unit (V-1) as the structural unit (V) with respect to the entire structural units constituting the fluorine-containing polymer (A2-1) is preferably 2 mol % to 90 mol %, and more preferably 5 mol % to 30 mol %. It is to be noted that the fluorine-containing polymer (A2-1) may include one, or two or more types of the structural unit (V-1).

### Structural Unit (V-2)

The structural unit (V-2) is represented by the following formula (6).

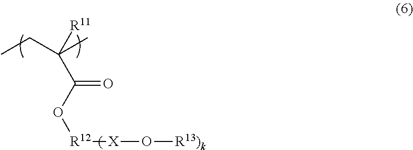

In the above formula (6), R¹¹ represents a hydrogen atom, a methyl group or a trifluoromethyl group; R¹² represents a linking group having a valency of (k+1); X represents a divalent linking group having a fluorine atom; R⁷ represents a hydrogen atom or a monovalent organic group; k is an integer of 1 to 3, wherein in the case where k is 2 or 3, a plurality of Xs and a plurality of R¹³s are each identical or different.

In the above formula (6), examples of the linking group having a valency of (k+1) represented by R¹² include a linear or branched hydrocarbon group having 1 to 30 carbon atoms, an alicyclic hydrocarbon group having 3 to 30 carbon atoms, an aromatic hydrocarbon group having 6 to 30 carbon atoms, or a group derived from any of these groups by combining with an oxygen atom, a sulfur atom, an ether group, an ester group, a carbonyl group, an imino group, an amide group or a combination thereof. In addition, the linking group having a valency of (k+1) does not have or has a substituent.

Examples of the linear or branched hydrocarbon group having 1 to 30 carbon atoms include groups derived from any of hydrocarbons such as methane, ethane, propane, butane, pentane, hexane, heptane, decane, icosane and triacontane by removing (k+1) hydrogen atoms therefrom.

Examples of the alicyclic hydrocarbon group having 3 to 30 carbon atoms include groups derived from any of the following hydrocarbons by removing (k+1) hydrogen atoms therefrom:

monocyclic saturated hydrocarbons such as cyclopropane, cyclobutane, cyclopentane, cyclohexane, cycloheptane, cyclooctane, cyclodecane, methylcyclohexane and ethylcyclohexane;

monocyclic unsaturated hydrocarbons such as cyclobutene, cyclopentene, cyclohexene, cycloheptene, cyclooctene, cyclodecene, cyclopentadiene, cyclohexadiene, cyclooctadiene and cyclodecadiene;

polycyclic saturated hydrocarbons such as bicyclo[2.2.1]heptane, bicyclo[2.2.2]octane, tricyclo[5.2.1.0^{2,6}]decane, tricyclo[3.3.1.1^{3,7}]decane, tetracyclo[6.2.1.1^{3,6}.0^{2,7}]dodecane and adamantane;

polycyclic hydrocarbon groups such as bicyclo[2.2.1]heptene, bicyclo[2.2.2]octene, tricyclo[5.2.1.0^{2,6}]decene, tricyclo[3.3.1.1^{3,7}]decene and tetracyclo[6.2.1.1^{3,6}.0^{2,7}]dodecene.

Examples of the aromatic hydrocarbon group having 6 to 30 carbon atoms include groups derived from any of aromatic hydrocarbons such as benzene, naphthalene, phenanthrene, anthracene, tetracene, pentacene, pyrene, picene, toluene, xylene, ethylbenzene, mesitylene and cumene by removing (k+1) hydrogen atoms therefrom.

In the above formula (6), the divalent linking group having a fluorine atom represented by X is exemplified by a divalent linear hydrocarbon group having 1 to 20 carbon atoms and having a fluorine atom. X is exemplified by structures represented by the following formulae (X-1) to (X-6), and the like.

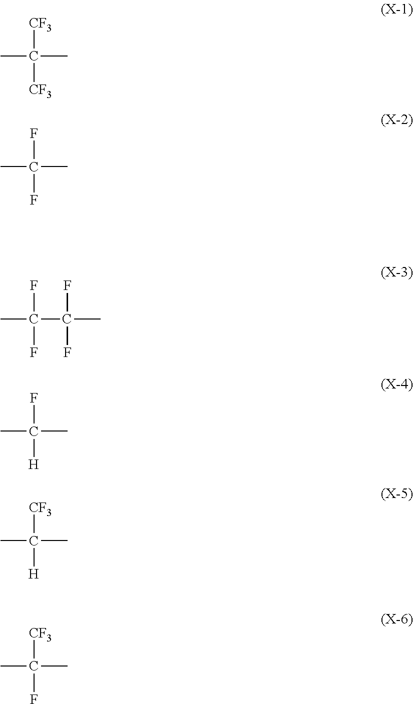

X preferably represents a structure represented by the above formulae (X-1) and (X-2).

In the above formula (6), the organic group represented by R¹³ is exemplified by a linear or branched hydrocarbon group having 1 to 30 carbon atoms, an alicyclic hydrocarbon group having 3 to 30 carbon atoms, an aromatic hydrocarbon group having 6 to 30 carbon atoms, or a group derived by combining such a group with an oxygen atom, a sulfur atom, an ether group, an ester group, a carbonyl group, an imino group, an amide group or a combination thereof.

Examples of the structural unit (V-2) include structural units represented by the following formulae (6-1) and (6-2).

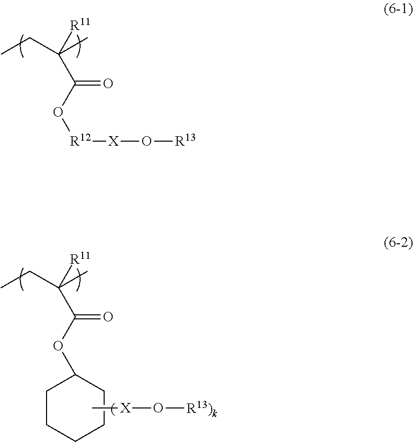

In the above formula (6-1), R¹² represents a divalent linear, branched or cyclic saturated or unsaturated hydrocarbon group having 1 to 20 carbon atoms; and R¹¹, X and R¹³ are as defined in the above formula (6).

In the above formula (6-2), R¹¹, X, R¹¹ and k are as defined in the above formula (6), wherein in the case where k is 2 or 3, a plurality of Xs and a plurality of R¹³s are each identical or different.

The structural units represented by the above formula (6-1) and formula (6-2) are exemplified by structural units represented by the following formula (6-1-1), formula (6-1-2) and formula (6-2-1).

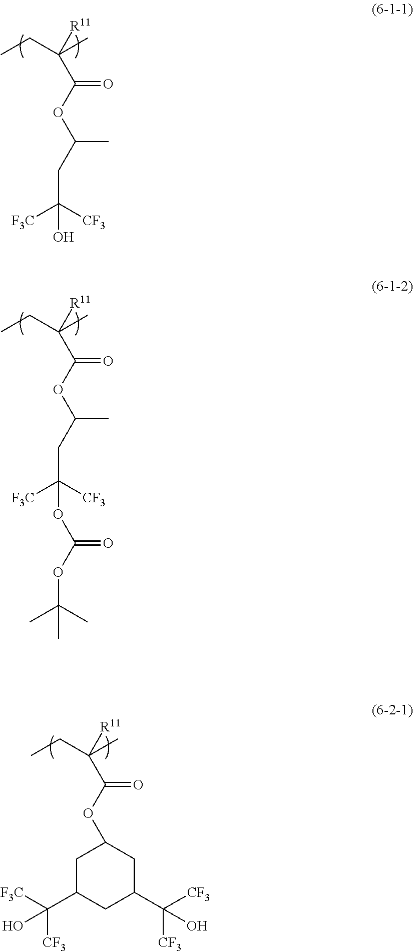

In the above formulae (6-1-1), (6-1-2) and (6-2-1), R¹¹ is as defined in the above formula (6).

Examples of the monomer that gives the structural unit (V-2) include (meth)acrylic acid (1,1,1-trifluoro-2-trifluoromethyl-2-hydroxy-3-propyl) ester, (meth)acrylic acid (1,1,1-trifluoro-2-trifluoromethyl-2-hydroxy-4-butyl) ester, (meth)acrylic acid (1,1,1-trifluoro-2-trifluoromethyl-2-hydroxy-5-pentyl) ester, (meth)acrylic acid (1,1,1-trifluoro-2-trifluoromethyl-2-hydroxy-4-pentyl) ester, (meth)acrylic acid 2-{[5-(1′,1′,1′-trifluoro-2′-trifluoromethyl-2′-hydroxy)propyl]bicyclo[2.2.1]heptyl}ester, and the like.

In the fluorine-containing polymer (A2-1), the content of the structural unit (V-2) with respect to the entire structural units constituting of the fluorine-containing polymer (A2-1) is preferably 20 mol % to 95 mol %, and more preferably 30 mol % to 90 mol %. It is to be noted that the fluorine-containing polymer (A2-1) may include one, or two or more types of the structural unit (V-2).

The proportion of the fluorine-containing polymer (A2-1) contained with respect to 100 parts by mass of the base polymer (A1) is preferably 1 part by mass to 50 parts by mass, and more preferably 2 parts by mass to 10 parts by mass. When the proportion of the fluorine-containing polymer (A2-1) is less than 1 part by mass, the effects of the embodiment of the present invention such as prevention of bridge defects, etc., a decrease of LWR, and the like may not be sufficiently achieved. Moreover, when the proportion exceeds 50 parts by mass, pattern formation properties may be deteriorated.

### Synthesis Method of Fluorine-Containing Polymer (A2-1)

The fluorine-containing polymer (A2-1) may be produced by, for example, polymerizing a monomer corresponding to each predetermined structural unit using a radical polymerization initiator in an appropriate solvent.

Examples of the solvent for use in the polymerization include those exemplified in the synthesis method of the base polymer (A1-1).

The reaction temperature in the polymerization is typically 40° C. to 150° C., and preferably 50° C. to 120° C. The reaction time period is typically 1 hr to 48 hrs, and preferably 1 hr to 24 hrs.

Mw of the fluorine-containing polymer (A2-1) in accordance with a GPC technique is preferably 1,000 to 100,000, more preferably 1,000 to 50,000, and particularly preferably 1,000 to 30,000. When Mw of the fluorine-containing polymer (A2-1) falls within the above range, solubility in a solvent of a resist sufficient for use as a resist is attained, and effects of preventing bridge defects, etc., and effects of decreasing LWR can be sufficiently exhibited.

The ratio (Mw/Mn) of Mw to Mn of the fluorine-containing polymer (A2-1) is typically 1 to 3, and preferably 1 to 2.

### Fluorine-Containing Polymer (A2-2)

The fluorine-containing polymer (A2-2) is a fluorine-containing polymer not including a structural unit (I) represented by the above formula (1). Since the fluorine-containing polymer (A2-2) can serve as a water-repellent additive, use of the fluorine-containing polymer (A2-2) in combination with the base polymer (A1-1) having a structural unit (I) enables the water repellency of the resulting resist film to be improved while securing the effects of the embodiment of the present invention. The fluorine-containing polymer (A2-2) preferably includes the structural unit (V) having a fluorine atom. In addition thereto, the structural unit (II) having the acid-labile group represented by the above formula (4), the structural unit (III) having a lactone skeleton or a cyclic carbonate skeleton, the structural unit (IV) having an alicyclic structure may be also included. With respect to descriptions of these structural units (II) to (IV), those in the base polymer (A1-1) may be applied, and with respect to descriptions of the structural unit (V), those in the fluorine-containing polymer (A2-1) may be applied.

In the fluorine-containing polymer (A2-2), the content of the structural unit (V-1) with respect to the entire structural units constituting the fluorine-containing polymer (A2-2) is preferably 10 mol % to 70 mol %, and more preferably mol % to 50 mol %. It is to be noted that the fluorine-containing polymer (A2-2) may include one, or two or more types of the structural unit (V-1).

In the fluorine-containing polymer (A2-2), the content of the structural unit (V-2) with respect to the entire structural units constituting the fluorine-containing polymer (A2-2) is preferably 20 mol % to 80 mol %, and more preferably mol % to 70 mol %. It is to be noted that the fluorine-containing polymer (A2-2) may include one, or two or more types of the structural unit (V-2).

The proportion of the fluorine-containing polymer (A2-2) contained with respect to 100 parts by mass of the polymer (A1-1) is preferably 1 part by mass to 15 parts by mass, and more preferably 2 parts by mass to 10 parts by mass.

### Synthesis Method of Fluorine-Containing Polymer (A2-2)

The fluorine-containing polymer (A2-2) may be produced by, for example, polymerizing a monomer corresponding to each predetermined structural unit using a radical polymerization initiator in an appropriate solvent. Note that with respect to a polymerization initiator, a solvent and the like for use in the synthesis of the fluorine-containing polymer (A2-2), those exemplified in the synthesis method of the polymer (A1-1) may be employed.

The reaction temperature in the polymerization is typically 40° C. to 150° C., and preferably 50° C. to 120° C. The reaction time period is typically 1 hr to 48 hrs, and preferably 1 hr to 24 hrs.

The polystyrene equivalent weight average molecular weight (Mw) of the fluorine-containing polymer (A2-2) as determined by a gel permeation chromatography (GPC) technique is preferably 1,000 to 100,000, more preferably 1,000 to 50,000, and particularly preferably 1,000 to 30,000. When the Mw of the polymer (A2-2) is less than 1,000, attaining a satisfactory advancing contact angle may fail. To the contrary, when the Mw of the polymer (A2-2) exceeds 50,000, developability when a resist is provided is tends to be inferior.

The ratio (Mw/Mn) of Mw to polystyrene equivalent number average molecular weight (Mn) as determined by a GPC method of the fluorine-containing polymer (A2-2) is typically 1 to 3, and preferably 1 to 2.

The content of the structural unit (I) in the entire polymers included in the polymer component (A) is, in terms of the total amount of the structural unit (I) with respect to the entire structural unit included in the polymer constituting the polymer component (A), is preferably 1 to 90 mol %, more preferably 5 to 70 mol %, and still more preferably 15 to 50 mol %. When the content falls within such a range, the sensitivity, the lithography performances in terms of LWR and DOF, and the etching resistance of the radiation-sensitive resin composition can be further improved. In addition, generation of bridge defects and scums of the radiation-sensitive resin composition can be suppressed.

### (B) Acid Generator

The acid generator (B) generates an acid upon exposure, and an acid-labile group present in the polymer component (A) is dissociated by way of the acid, thereby generating an acid. As a result, the polymer component (A) becomes soluble in a developer solution. The form of the acid generator (B) contained in the radiation-sensitive resin composition may be in the form of either a compound as described later or a form incorporated as a part of the polymer described later, or may be in both of these forms.

The acid generator (B) is exemplified by onium salt compounds such as sulfonium salts and iodonium salts, organic halogen compounds, sulfone compounds such as disulfones and diazomethanesulfones, and the like. Of these, specific examples of suitable acid generating agent (B) include compounds described in paragraphs nos. [0080] to [0113] of Japanese Unexamined Patent Application, Publication No. 2009-134088, and the like.

Specifically, examples of the acid generating agent (B) preferred include:

diphenyliodonium trifluoromethanesulfonate, diphenyliodonium nonafluoro-n-butanesulfonate, diphenyliodonium perfluoro-n-octanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, triphenylsulfonium trifluoromethanesulfonate, triphenylsulfonium nonafluoro-n-butanesulfonate, triphenylsulfonium perfluoro-n-octanesulfonate, cyclohexyl 2-oxocyclohexylmethylsulfonium trifluoromethanesulfonate, dicyclohexyl 2-oxocyclohexylsulfonium trifluoromethanesulfonate, 2-oxocyclohexyldimethylsulfonium trifluoromethanesulfonate, 4-hydroxy-1-naphthyldimethylsulfonium trifluoromethanesulfonate,

4-hydroxy-1-naphthyltetrahydrothiophenium trifluoromethanesulfonate, 4-hydroxy-1-naphthyltetrahydrothiophenium nonafluoro-n-butanesulfonate, 4-hydroxy-1-naphthyltetrahydrothiophenium perfluoro-n-octanesulfonate, 1-(1-naphthylacetomethyl)tetrahydrothiophenium trifluoromethanesulfonate, 1-(1-naphthylacetomethyl)tetrahydrothiophenium nonafluoro-n-butanesulfonate, 1-(1-naphthylacetomethyl)tetrahydrothiophenium perfluoro-n-octanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate,

trifluoromethanesulfonyl bicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, N-hydroxysuccinimidetrifluoromethanesulfonate, N-hydroxysuccinimidenonafluoro-n-butanesulfonate, N-hydroxysuccinimideperfluoro-n-octanesulfonate, and 1,8-naphthalenedicarboxylic acid imidetrifluoromethanesulfonate.

These acid generators (B) may be used either alone, or two or more types thereof may be used in combination. The amount of the acid generator (B) used with respect to 100 parts by mass of the base polymer (A1) is typically no less than 0.1 parts by mass and no greater than 20 parts by mass, and preferably no less than 0.5 parts by mass and no greater than 15 parts by mass, in light of securing the sensitivity and developability as a resist. In this instance, when the amount of the acid generating agent (B) used is less than 0.1 parts by mass, the sensitivity and the developability tend to be inferior, whereas when the amount exceeds 15 parts by mass, transparency for radioactive rays is lowered, and thus it may be difficult to obtain a desired resist pattern.

### Other Optional Components

In addition to the polymer component (A) and the acid generator (B), the composition may contain an acid diffusion controller, a solvent, a surfactant, an alicyclic skeleton-containing compound, a sensitizing agent and the like as other optional components within a range not leading to impairment of the effects of the embodiment of the present invention.

### Acid Diffusion Controller

The acid diffusion controller exerts the effect of controlling diffusion phenomenon of the acid generated from the acid generator (B) upon the exposure in the resist coating film, and inhibiting unfavorable chemical reactions in unexposed regions; as a result, storage stability of the resultant radiation-sensitive resin composition is further improved, and resolution of the resist is further improved, while preventing variation of the line width of the resist pattern caused by variation of post-exposure delay from the exposure until a development treatment, which enables the radiation-sensitive resin composition with superior process stability to be obtained. The mode of incorporation of the acid diffusion controller into the composition may be in a free compound form (hereinafter, may be also referred to as “acid diffusion control agent”) or in an incorporated form as a part of the polymer, or in both of these forms.

The acid diffusion controller is exemplified by a compound represented by the following formula (7) (hereinafter, referred to as “nitrogen-containing compound (i)”), a compound having two nitrogen atoms within a single molecule (hereinafter, referred to as “nitrogen-containing compound (II)”), a compound having three or more nitrogen atoms (hereinafter, referred to as “nitrogen-containing compound (iii)”), an amide group-containing compound, a urea compound, a nitrogen-containing heterocyclic compound, and the like.

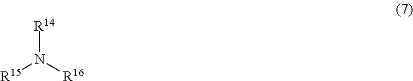

In the above formula (7), R¹⁴ to R¹⁶ each independently represent a hydrogen atom, a linear, a branched or cyclic alkyl group, an aryl group, or an aralkyl group that is substituted or unsubstituted.

Examples of the nitrogen-containing compound (i) include: monoalkylamines such as n-hexylamine; dialkylamines such as di-n-butylamine; trialkylamines such as triethylamine; aromatic amines such as aniline, and the like.

Examples of the nitrogen-containing compound (II) include ethylenediamine, N,N,N′,N′-tetramethylethylenediamine, and the like.

Examples of the nitrogen-containing compound (iii) include polymers such as polyethyleneimine, polyallylamine and dimethylaminoethylacrylamide, and the like.

Examples of the amide group-containing compound include formamide, N-methylformamide, N,N-dimethylformamide, acetamide, N-methylacetamide, N,N-dimethylacetamide, propionamide, benzamide, pyrrolidone, N-methylpyrrolidone, and the like.

Examples of the urea compound include urea, methylurea, 1,1-dimethylurea, 1,3-dimethylurea, 1,1,3,3-tetramethylurea, 1,3-diphenylurea, tributylthiourea, and the like.

Examples of the nitrogen-containing heterocyclic compound include pyridines such as pyridine and 2-methylpyridine, as well as pyrazine, pyrazole, and the like.

In addition, as the aforementioned nitrogen-containing organic compound, a compound having an acid-labile group may be also used. Examples of the nitrogen-containing organic compound having such an acid-labile group include N-(t-butoxycarbonyl)piperidine, N-(t-butoxycarbonyl)imidazole, N-(t-butoxycarbonyl)benzimidazole, N-(t-butoxycarbonyl)-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-(t-butoxycarbonyl)-4-hydroxypiperidine, and the like.

Alternatively, as the acid diffusion controller, a compound represented by the following formula (8) may be also used.

X^{D+}Z^{D-} (8)

In the above formula (8), X^{D+} is a cation represented by the following formula (8-1-1) or (8-1-2); Z^{D-} is OH⁻, an anion represented by R^{D1}—COO⁻, an anion represented by R^{D1}—SO₃⁻ or an anion represented by R^{D1}—N⁻—SO₂—R^{D2}, wherein in these formulae, R^{D1} represents an alkyl group, a monovalent aliphatic cyclic hydrocarbon group or an aryl group that is substituted or unsubstituted; and R^{D2} represents an alkyl group or a monovalent aliphatic cyclic hydrocarbon group in which a part or all of hydrogen atoms are substituted by a fluorine atom.

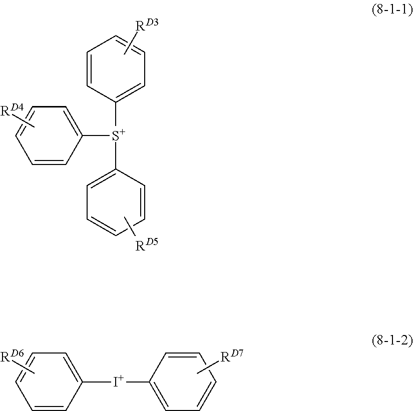

In the above formula (8-1-1), R^{D3} to R^{D5} each independently represent a hydrogen atom, an alkyl group, an alkoxyl group, a hydroxyl group, or a halogen atom. In the above formula (8-1-2), R^{D6} and R^{D7} each independently represent a hydrogen atom, an alkyl group, an alkoxyl group, a hydroxyl group, or a halogen atom.

The aforementioned compound is used as an acid diffusion controller (hereinafter, may be also referred to as “photodegradable acid diffusion controller”) that loses acid diffusion controllability upon decomposition by exposure. When this compound is contained, the acid is diffused at a site exposed with light, whereas diffusion of the acid is controlled at a site unexposed with light, whereby an excellent contrast between the site exposed with light and the site unexposed with light is attained, in other words, a boundary between the light-exposed site and the site unexposed with light becomes clear. Therefore, it is particularly effective in improving the LWR and MEEF (Mask Error Enhancement Factor) of the radiation-sensitive resin composition of the embodiment of the present invention.

In the above formula (8), X^{D+} is a cation represented by the general formula (8-1-1) or (8-1-2) as described above. In addition, R^{D3} to R^{D5} in the above formula (8-1-1) each independently represent a hydrogen atom, an alkyl group, an alkoxyl group, a hydroxyl group, or halogen atom, and among these, a hydrogen atom, an alkyl group, an alkoxy group or a halogen atom is preferred due to exhibiting an effect of decreasing the solubility of the compound in a developer solution. Additionally, R^{D6} and R^{D7} in the above formula (8-1-2) each independently represent a hydrogen atom, an alkyl group, an alkoxyl group, a hydroxyl group, or a halogen atom, and of these, a hydrogen atom, an alkyl group, or a halogen atom is preferred.

In the above formula (8), Z⁻ is an anion represented by OH⁻ or R^{D1}—COO⁻, an anion represented by R^{D1}—SO₃⁻, or an anion represented by a formula R^{D1}—N⁻—SO₂—R^{D2}, wherein R^{D1} in these formulae represents an alkyl group, an aliphatic cyclic hydrocarbon group or an aryl group that is substituted or unsubstituted, and among these, an aliphatic cyclic hydrocarbon group or an aryl group is preferred due to exhibiting the effects of decreasing the solubility of the compound in a developer solution.

Examples of the unsubstituted or substituted alkyl group in the above formula (8) include hydroxyalkyl groups having 1 to 4 carbon atoms such as a hydroxymethyl group; alkoxyl groups having 1 to 4 carbon atoms such as a methoxy group; cyano groups; groups having one or more substituents such as a cyano alkyl group having 2 to 5 carbon atoms such as a cyano methyl group, and the like. Of these, a hydroxymethyl group, a cyano group, and a cyano methyl group are preferred.

Examples of the unsubstituted or substituted aliphatic cyclic hydrocarbon group in the above formula (8) include monovalent groups derived from an aliphatic cyclic hydrocarbon such as a bridged aliphatic cyclic hydrocarbon skeleton, etc., for example: a cycloalkane skeleton such as hydroxycyclopentane, hydroxycyclohexane or cyclohexanone; a bridged aliphatic cyclic hydrocarbon skeleton such as 1,7,7-trimethyl bicyclo[2.2.1]heptan-2-one (camphor), and the like. Of these, groups derived from 1,7,7-trimethyl bicyclo[2.2.1]heptan-2-one are preferred.

Examples of the unsubstituted or substituted aryl group in the above formula (8) include a phenyl group, a benzyl group, a phenylethyl group, a phenylpropyl group, a phenylcyclohexyl group and the like, and those obtained by substituting these compounds with a hydroxyl group, a cyano group or the like, and the like. Of these, a phenyl group, a benzyl group or a phenylcyclohexyl group is preferred.

Z⁻ in the above formula (8) is preferably an anion represented by the following formula (8-2-1) (i.e., an anion represented by R^{D1}—COO⁻, wherein R^{D1} is a phenyl group), an anion represented by the following formula (8-2-2) (i.e., an anion represented by R^{D1}—SO₃⁻, wherein R^{D1} is a group derived from 1,7,7-trimethyl bicyclo[2.2.1]heptan-2-one) or an anion represented by the following formula (8-2-3) (i.e., an anion represented by R^{D1}—N⁻—SO₂—R^{D2}, wherein R^{D1} is a butyl group, and R^{D2} is a trifluoromethyl group).

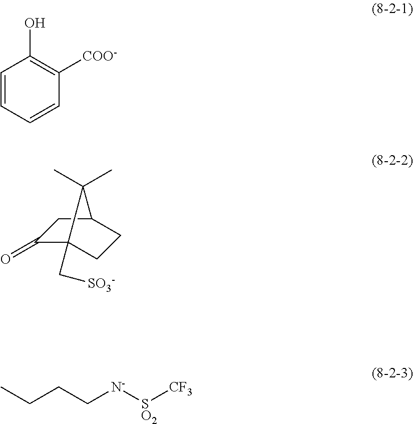

The photodegradable acid diffusion controller is represented by the above formula (8), and specifically, is a sulfonium salt compound or an iodonium salt compound that meets the definition in the foregoing.

Examples of the sulfonium salt compound include triphenylsulfonium hydroxide, triphenylsulfonium salicylate, triphenylsulfonium 4-trifluoromethyl salicylate, diphenyl-4-hydroxyphenylsulfonium salicylate, triphenylsulfonium 10-camphorsulfonate, 4-t-butoxyphenyl diphenylsulfonium 10-camphorsulfonate, and the like. It is to be noted that these sulfonium salt compounds may be used either alone of one type, or in combination of two or more types thereof.

In addition, examples of the iodonium salt compound include bis(4-t-butylphenyl)iodonium hydroxide, bis(4-t-butylphenyl)iodonium salicylate, bis(4-t-butylphenyl)iodonium 4-trifluoromethyl salicylate, bis(4-t-butylphenyl)iodonium 10-camphorsulfonate, and the like. It is to be noted that these iodonium salt compounds may be used either alone of one type, or in combination of two or more types thereof.

These acid diffusion control agents may be used either alone, or two or more types thereof may be used in combination. The content of the acid diffusion control agent is preferably less than 10 parts by mass with respect to 100 parts by mass of the base polymer (A1). When the total amount exceeds 10 parts by mass, sensitivity as a resist is likely to be lowered.

### Solvent

The composition usually contains a solvent. The solvent is not particularly limited as long as it can dissolve at least the polymer component (A), the acid generator (B), and the other optional component(s) described above. The solvent is exemplified by an alcohol solvent, an ether solvent, a ketone solvent, an amide solvent, an ester solvent and a mixed solvent thereof, and the like.

Examples of the alcohol solvent include:

monoalcohol solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethyl nonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol and diacetone alcohol;

polyhydric alcohol solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol and tripropylene glycol;

partially etherified polyhydric alcohol solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether and dipropylene glycol monopropyl ether, and the like.

Examples of the ether solvent include diethyl ether, dipropyl ether, dibutyl ether, diphenyl ether, methoxybenzene, and the like.

Examples of the ketone solvent include ketone solvents such as acetone, methyl ethyl ketone, methyl-n-propyl ketone, methyl-n-butyl ketone, diethyl ketone, methyl-iso-butyl ketone, methyl-n-pentyl ketone, ethyl-n-butyl ketone, methyl-n-hexyl ketone, di-iso-butyl ketone, trimethyl nonanone, cyclopentanone, cyclohexanone, cycloheptanone, cyclooctanone, methyl cyclohexanone, 2,4-pentanedione, acetonyl acetone, acetophenone, and the like.

Examples of the amide solvent include N,N′-dimethylimidazolidinone, N-methylformamide, N,N-dimethylformamide, N,N-diethylformamide, acetamide, N-methylacetamide, N,N-dimethylacetamide, N-methylpropionamide, N-methylpyrrolidone, and the like.

Examples of the ester solvent include diethyl carbonate, propylene carbonate, methyl acetate, ethyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, diglycol acetate, methoxytriglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, diethyl phthalate, and the like.

Examples of the hydrocarbon solvent include:

aliphatic hydrocarbon solvents such as n-pentane, iso-pentane, n-hexane, iso-hexane, n-heptane, iso-heptane, 2,2,4-trimethyl pentane, n-octane, iso-octane, cyclohexane and methylcyclohexane;

aromatic hydrocarbon solvents such as benzene, toluene, xylene, mesitylene, ethylbenzene, trimethyl benzene, methylethylbenzene, n-propylbenzene, iso-propylbenzene, diethylbenzene, iso-butylbenzene, triethylbenzene, di-iso-propylbenzene and n-amylnaphthalene, and the like.

Of these, n-butyl acetate, isopropyl acetate, amyl acetate, methylethyl ketone, methyl-n-butyl ketone and methyl-n-pentyl ketone are preferred. These solvents may be used either alone, or two or more types thereof may be used in combination.

Of these, propylene glycol monomethyl ether acetate, and cyclohexanone are preferred. These solvents may be used either alone, or two or more types thereof may be used in combination.

### Surfactant

The surfactant exhibits an effect of improving coating properties, striation, developability, and the like. Examples of the surfactant include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate, as well as trade names KP341 (manufactured by Shin-Etsu Chemical Co., Ltd.), Polyflow No. 75 and Polyflow No. 95 (both Kyoeisha Chemical Co., Ltd.), EFTOP EF301, EFTOP EF303 and EFTOP EF352 (all Tochem Products Corporation), Megaface® F171 and Megaface® F173 (both Dainippon Ink And Chemicals, Incorporated), Fluorad™ FC430 and Fluorad™ FC431 (both Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (all Asahi Glass Co., Ltd.), and the like. These surfactants may be used either alone, or two or more types thereof may be used in combination.

### Alicyclic Skeleton-Containing Compound

The alicyclic skeleton-containing compound exhibits an effect of improving the dry etching resistance, pattern configuration, adhesiveness to a substrate, and the like.

Examples of the alicyclic skeleton-containing compound include: adamantane derivatives such as 1-adamantanecarboxylic acid, 2-adamantanone and t-butyl 1-adamantanecarboxylate; deoxycholic acid esters such as t-butyl deoxycholate, t-butoxycarbonylmethyl deoxycholate and 2-ethoxyethyl deoxycholate; lithocholic acid esters such as t-butyl lithocholate, t-butoxycarbonylmethyl lithocholate and 2-ethoxyethyl lithocholate; 3-[2-hydroxy-2,2-bis(trifluoromethyl)ethyl]tetracyclo[4.4.0.1^{2,5}.1^{7,10}]dodecane, 2-hydroxy-9-methoxycarbonyl-5-oxo-4-oxa-tricyclo[4.2.1.0^{3,7}]nonane, and the like. These alicyclic skeleton-containing compounds may be used either alone, or two or more types thereof may be used in combination.

### Sensitizing Agent

The sensitizing agent has an action of increasing the amount of production of the acid generator (B), and thus has an effect of improving “apparent sensitivity” of the resin composition.

Examples of the sensitizing agent include carbazoles, acetophenones, benzophenones, naphthalenes, phenols, biacetyl, eosin, rose bengal, pyrenes, anthracenes, phenothiazines, and the like. These sensitizing agents may be used either alone, or two or more types thereof may be used in combination.

### Preparation of Radiation-Sensitive Resin Composition

The radiation-sensitive resin composition may be prepared by, for example, mixing the polymer component (A), the acid generator (B), and the other optional component at a certain ratio in an organic solvent. Also, the radiation-sensitive resin composition may be prepared to give a state of dissolving or dispersing in an appropriate organic solvent, and then used.

### Pattern-Forming Method

According to still another embodiment of the present invention, a pattern-forming method includes: (1) a resist film-forming step of providing a resist film on a substrate using the radiation-sensitive resin composition of the embodiment of the present invention; (2) an exposure step of irradiating at least a part of the resist film with a radioactive ray; (3) a heating step of heating the exposed resist film; and (4) a development step of developing the heated resist film. Hereinafter, each step will be described in detail.

### Step (1)

In this step, the radiation-sensitive resin composition of the embodiment of the present invention is coated on a substrate to provide a resist film. As the substrate, for example, conventionally well-known substrates such as a silicon wafer and a wafer coated with aluminum can be used. In addition, organic or inorganic antireflective films disclosed in, for example, Japanese Examined Patent Application, Publication No. H06-12452, Japanese Unexamined Patent Application, Publication No. S59-93448, and the like may be provided on the substrate.

A coating method is exemplified by spin-coating, cast coating, roll coating, and the like. It is to be noted that the film thickness of the resist film provided is typically 0.01 μm to 1 μm, and preferably 0.01 μm to 0.5 μm.

After coating the radiation-sensitive resin composition, a solvent in the coating film may be volatilized as needed by prebaking (PB). The conditions of heating for PB may be appropriately selected depending on the formulation of the photoresist composition, and may involve typically about 30° C. to 200° C. and preferably 50° C. to 150° C.

In order to prevent influences of basic impurities etc., included in the environment atmosphere, a protective film disclosed in, for example, Japanese Unexamined Patent Application, Publication No. H5-188598, and the like, may be also provided on the resist film. Furthermore, in order to prevent effluence of the acid generator etc., from the resist layer, a protective film for liquid immersion may be provided on the resist layer disclosed in, for example, Japanese Unexamined Patent Application, Publication No. 2005-352384, and the like. It is to be noted that these techniques may be used in combination.

### Step (2)

In this step, the resist film provided in the step (1) is exposed at a desired region by carrying out reduction projection through a mask having a specific pattern, and an immersion liquid as needed. For example, an isolated trench (iso-trench) pattern can be formed by carrying out reduced projection exposure at a desired region through a mask having an isolated line (iso-line) pattern. Also, the exposure may be carried out at least twice depending on the desired pattern and the mask pattern. When the exposure is carried out at least twice, the exposure is preferably carried out continuously. When the exposure is carried out a plurality of times, for example, first reduced projection exposure is carried out through a line-and-space pattern mask at a desired region, and subsequently second reduced projection exposure is carried out such that lines cross over light-exposed sites subjected to the first exposure. The first light-exposed sites are preferably orthogonal to the second light-exposed sites. Due to being orthogonal with each other, a perfectly circular contact hole pattern can be easily formed at light-unexposed sites surrounded by light-exposed sites. It is to be noted that examples of the immersion liquid for use in the exposure include water, a fluorine-containing inert liquid, and the like. It is preferred that the immersion liquid be transparent to the exposure wavelength, and has a temperature coefficient of the refractive index as small as possible so that distortion of an optical image projected onto the film is minimized. When using an ArF excimer laser (wavelength: 193 nm) as the exposure light source, it is preferred to use water from the viewpoint of availability and ease of handling, in addition to the viewpoints described above. When water is used, a marginal amount of an additive which reduces the surface tension of water and imparts enhanced surfactant power may be added. It is preferred that the additive hardly dissolves a resist layer on a wafer and has a negligible influence on an optical coating of an inferior face of a lens. The water for use is preferably distilled water.

A radioactive ray used for the exposure is appropriately selected in accordance with the type of the acid generator (B), and is exemplified by an ultraviolet ray, a far ultraviolet ray, an X-ray, a charged particle ray, and the like. Among these, a far ultraviolet ray typified by an ArF excimer laser or a KrF excimer laser (wavelength: 248 nm) is preferred, and an ArF excimer laser is more preferred. The exposure conditions such as an exposure dose are appropriately selected in accordance with the formulation, and type of additives etc. of the radiation-sensitive resin composition. The pattern-forming method of the embodiment of the present invention may include a plurality of the exposure steps, and light sources employed in the exposure carried out a plurality of times may be identical or different, but an ArF excimer laser beam is preferably used in the first exposure.

### Step (3)

In this step, post-exposure baking (PEB) is carried out after the exposure. When the PEB is carried out, a dissociation reaction of an acid-labile group in the radiation-sensitive resin composition can smoothly proceed. The conditions of heating for PEB is typically no less than 30° C. and less than 200° C., preferably no less than 50° C. and less than 150° C., and more preferably no less than 60° C. and less than 100° C. At a temperature lower than 30° C., the dissociation reaction may not smoothly proceed, whereas at a temperature of no less than 200° C., the acid generated may be broadly diffused from the acid generator (B) to light-unexposed sites, whereby obtaining a favorable pattern may fail. In the pattern-forming method in which the radiation-sensitive resin composition of the embodiment of the present invention is used, it is possible to lower the temperature of PEB as compared with commonly employed temperatures; therefore, diffusion of the acid can be appropriately controlled, and thus a favorable pattern can be obtained. In addition, energy consumption can be saved, whereby lowering of the cost can be realized.

### Step (4)

In this step, the heated photoresist film after the exposure is developed with a developer solution to form a predetermined photoresist pattern. After the development, washing with water, and drying are generally carried out. Examples of preferable developer solution include aqueous alkali solutions prepared by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene or 1,5-diazabicyclo-[4.3.0]-5-nonene.

Examples of the development method include a dipping method that immerses the substrate in a container filled with the developer for a given time, a puddle method that allows the developer to be present on the surface of the substrate due to surface tension for a given time, a spraying method that sprays the developer onto the surface of the substrate, a dynamic dispensing method that applies the developer to the substrate that is rotated at a constant speed while scanning with a developer application nozzle at a constant speed, and the like.

### Polymer

The polymer of the embodiment of the present invention has a structural unit (I) represented by the above formula (1). The polymer has a structure in which a linear alkyl group having 5 or more carbon atoms bonds to a carbon atom to which an ester group bonds in an alicyclic hydrocarbon group or an aliphatic heterocyclic group. The alicyclic hydrocarbon group or the aliphatic heterocyclic group is likely to be dissociated by way of an acid, due to having the above-specified structure. Thus, according to the radiation-sensitive resin composition containing the polymer, it is possible to sufficiently proceed a dissociation reaction by an acid can even if the temperature of PEB is lowered than conventional temperatures. When the temperature of PEB can be thus lowered, diffusion of the acid is inhibited, and bulky molecules dissociated by the acid can further inhibit the diffusion of the acid; therefore, formation of a favorable fine pattern is enabled. Accordingly, the polymer can be suitably used as a component of, for example, radiation-sensitive resin compositions for use in lithography techniques, and the like.

Note that with regard to the polymer of the embodiment of the present invention, descriptions of the base polymer (A1-1) and the fluorine-containing polymer (A2-1) of the polymer component (A) in the radiation-sensitive resin composition may be applied.

### Compound

Since the compound of the embodiment of the present invention has the structure represented by the above formula (2), it can be suitably used as a monomer compound for incorporating the structural unit (1) into the polymer.

In the above formula (2), R² represents a hydrogen atom, a fluorine atom, a methyl group or a trifluoromethyl group; R² represents a linear alkyl group having 5 to 21 carbon atoms; and Z represents a divalent alicyclic hydrocarbon group or an aliphatic heterocyclic group having a ring skeleton which has 4 to 20 atoms, wherein a part or all of hydrogen atoms included in the alicyclic hydrocarbon group and the aliphatic heterocyclic group represented by Z are not substituted or substituted.

With regard to each group represented by R² and Z, descriptions of the above formula (1) of the polymer component (A) may be applied.

### Synthesis Method of Compound

A synthesis method of the compound is, for example, as shown below, and the compound may be synthesized according to the following scheme.

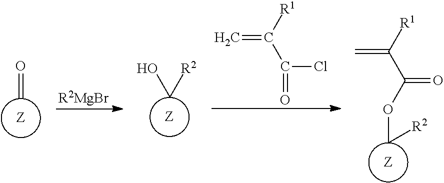

In the above formula, R¹, R² and Z are as defined in the above formula (2).

A 1-n-alkyl-substituted cyclic alcohol compound is obtained by allowing a cyclic carbonyl compound to react with n-alkylmagnesium bromide (i.e., Grignard reagent) prepared from 1-bromo straight-chain alkane and magnesium in a solvent such as diethyl ether. This cyclic alcohol compound is reacted with (meth)acryloyl chloride, etc., in the presence of a base such as an organic amine, whereby the compound represented by the above formula (2) can be obtained.

### EXAMPLES

Hereinafter, the present invention will be explained more specifically by way of Examples, but the present invention is not limited to these Examples.

The Mw and the Mn of the polymer were determined using GPC columns (Tosoh Corporation, “G2000HXL”×2, “G3000HXL”×1, and “G4000HXL”×1) under the following conditions.

column temperature: 40° C.
elution solvent: tetrahydrofuran (Wako Pure Chemical Industries, Ltd.)
flow rate: 1.0 mL/min
sample concentration: 1.0% by mass
amount of the sample injected: 100 μL
detector: differential refractometer
standaed substance: monodisperse polystyrene

The ¹H-NMR analysis and the ¹³C-NMR analysis were conducted using a nuclear magnetic resonance apparatus (JEOL, Ltd., JNM-EX270) for the measurement.

### Synthesis of Compound

### Example 1

### Synthesis of 1-pentylcyclopentyl methacrylate (M-1)

Into a 1 L reaction vessel equipped with a stirrer and a dropping funnel were charged 18.5 g (220 mmol) of cyclopentanone and 200 mL of diethyl ether, and 100 mL of a 2 M diethyl ether solution of pentylmagnesium bromide (200 mmol) was added dropwise through a dropping funnel under nitrogen. Then the mixture was stirred at 20° C. for 16 hrs to permit a reaction. After the reaction, a mixture of 24.5 g (242 mmol) of triethylamine and 25.3 g (242 mmol) of methacryloyl chloride was added dropwise through a dropping funnel while cooling the interior of the reaction vessel to 0° C. The mixture was stirred at 20° C. for 2 hrs to permit a reaction. The suspension liquid thus obtained was filtrated under reduced pressure, and the filtrate was concentrated in vacuo. Thus resulting residue was purified by subjecting to silica gel column chromatography (eluent: hexane/ethyl acetate=100/1) to obtain 19.0 g of colorless oil of 1-pentylcyclopentyl methacrylate represented by the following formula (M-1) (yield: 45%).

¹H-NMR data of the 1-pentylcyclopentyl methacrylate obtained are shown below.

¹H-NMR (CDCl₃) δ: 0.87 (t, 3H, CH₃), 1.27 (br, 6H, CH₂) 1.56-1.80 (m, 6H, CH₂), 1.89 (s, 3H, CH₃), 1.94-2.03 (m, 2H, CH₂), 2.10-2.24 (m, 2H, CH₂), 5.46 (s, 1H, CH), 6.00 (s, 1H, CH)

### Example 2

### Synthesis of 1-hexylcyclopentyl methacrylate (M-2)

A colorless oil in an amount of 20.1 g of 1-hexylcyclopentyl methacrylate represented by the following formula (M-2) was obtained (total yield: 45%) in a similar manner to Example 1 except that 100 mL of a 2 M diethyl ether solution of hexylmagnesium bromide was used in place of 100 mL of the 2 M diethyl ether solution of pentylmagnesium bromide as a starting material in Example 1.

¹H-NMR data of the 1-hexylcyclopentyl methacrylate obtained are shown below.

¹H-NMR (CDCl₃) δ: 0.87 (t, 3H, CH₃), 1.27 (br, 8H, CH₂) 1.55-1.79 (m, 6H, CH₂), 1.90 (s, 3H, CH₃), 1.92-2.00 (m, 2H, CH₂), 2.11-2.26 (m, 2H, CH₂), 5.46 (s, 1H, CH), 6.00 (s, 1H, CH)

### Example 3

### Synthesis of 1-octylcyclopentyl methacrylate (M-3)

A colorless oil in an amount of 19.5 g of 1-octylcyclopentyl methacrylate represented by the following formula (M-3) was obtained (total yield: 37%) in a similar manner to Example 1 except that 100 mL of a 2 M diethyl ether solution of octylmagnesium bromide was used in place of 100 mL of the 2 M diethyl ether solution of pentylmagnesium bromide as a starting material in Example 1.

¹H-NMR data of the 1-octylcyclopentyl methacrylate obtained are shown below.

¹H-NMR (CDCl₃) δ: 0.88 (t, 3H, CH₃), 1.30 (br, 12H, CH₂) 1.45-1.91 (m, 6H, CH₂), 1.90 (s, 3H, CH₃), 1.91-2.08 (m, 2H, CH₂), 2.06-2.31 (m, 2H, CH₂), 5.44 (s, 1H, CH), 5.98 (s, 1H, CH)

### Example 4

### Synthesis of 1-hexylcyclohexyl methacrylate (M-4)

A colorless oil in an amount of 18.6 g of 1-hexylcyclohexyl methacrylate represented by the following formula (M-4) was obtained (total yield: 56%) in a similar manner to Example 1 except that 100 mL of a 2 M diethyl ether solution of hexylmagnesium bromide was used in place of 100 mL of the 2 M diethyl ether solution of pentylmagnesium bromide as a starting material, and that 21.6 g (220 mmol) of cyclohexanone was used in place of 18.5 g of cyclopentanone in Example 1.

¹H-NMR data of the 1-hexylcyclohexyl methacrylate obtained are shown below.

¹H-NMR (CDCl₃) δ: 0.88 (t, 3H, CH₃), 1.12-1.40 (m, 8H), 1.84-2.08 (m, 15H), 5.48 (s, 1H, CH), 6.05 (s, 1H, CH)

### Example 5

### Synthesis of 1-hexylcyclooctyl methacrylate (M-5)

A colorless oil in an amount of 10.2 g of 1-hexylcyclooctyl methacrylate represented by the following formula (M-5) was obtained (total yield: 26%) in a similar manner to Example 1 except that 100 mL of a 2 M diethyl ether solution of hexylmagnesium bromide was used in place of 100 mL of the 2 M diethyl ether solution of pentylmagnesium bromide as a starting material, and that 27.8 g (220 mmol) of cyclooctanone was used in place of 18.5 g of cyclopentanone in Example 1.

¹H-NMR data of the 1-hexylcyclooctyl methacrylate obtained are shown below.

¹H-NMR (CDCl₃) δ: 0.87 (t, 3H, CH₃), 1.17-1.36 (m, 8H), 1.40-1.69 (m, 10H), 1.72-1.83 (m, 2H), 1.89-1.97 (m, 5H), 2.19-2.29 (m, 2H), 5.46 (s, 1H, CH), 6.00 (s, 1H, CH)

### Example 6

### Synthesis of 4-hexyltetrahydro-2H-pyran-4-yl methacrylate (M-6)

A colorless oil in an amount of 33.6 g of 4-hexyltetrahydro-2H-pyran-4-yl methacrylate represented by the following formula (M-6) was obtained (total yield: 66%) in a similar manner to Example 1 except that 100 mL of a 2 M diethyl ether solution of hexylmagnesium bromide was used in place of 100 mL of the 2 M diethyl ether solution of pentylmagnesium bromide as a starting material, and that 22.0 g (220 mmol) of tetrahydropyran-4-one was used in place of 18.5 g of cyclopentanone in Example 1.

¹H-NMR data of the 4-hexyltetrahydro-2H-pyran-4-yl methacrylate obtained are shown below.

¹H-NMR (CDCl₃) δ: 0.88 (t, 3H, CH₃), 1.15-1.40 (m, 8H), 1.51-2.13 (m, 9H), 3.43-3.61 (m, 4H), 5.46 (s, 1H, CH), 6.00 (s, 1H, CH)

### Example 7

### Synthesis of 2-hexyl-2-adamantane methacrylate (M-7)

A colorless oil in an amount of 13.9 g of 2-hexyl-2-adamantane methacrylate represented by the following formula (M-7) was obtained (total yield: 23%) in a similar manner to Example 1 except that 100 mL of a 2 M diethyl ether solution of hexylmagnesium bromide was used in place of 100 mL of the 2 M diethyl ether solution of pentylmagnesium bromide as a starting material, and that 33.0 g (220 mmol) of 2-adamantanone was used in place of 18.5 g of cyclopentanone in Example 1.

¹H-NMR data of the 2-hexyl-2-adamantane methacrylate obtained are shown below.

¹H-NMR (CDCl₃) δ: 0.86 (t, 3H, CH₃), 1.13-1.52 (m, 8H), 1.60-2.16 (m, 16H), 1.80-1.94 (m, 3H), 5.33 (dd, 1H, CH₂), 6.08 (dd, 1H, CH₂)

The following two types of the polymer component (A) were prepared:

1. a type in which the base polymer (A1-1) and the fluorine-containing polymer (A2-2) are contained; and

2. a type in which the base polymer (A1-2) and the fluorine-containing polymer (A2-1) are contained.

It is to be noted that the polymer component 1 described above was evaluated on sensitivity, LWR, DOF, and etching resistance, whereas the polymer component 2 was evaluated on pattern formation property, LWR, generation of scum, and bridge defect-preventing performances.

### 1. Type in which the Base Polymer (A1-1) and the Fluorine-Containing Polymer (A2-2) are Contained

### Synthesis of Polymer (A1-1)

Monomers used for the synthesis of the polymer (A1-1) and the fluorine-containing polymer (A2-2) described later are represented by the following formulae (M-1) to (M-14).

### Example 8

A monomer solution was prepared by dissolving 30.7 g (30 mol %) of the compound (M-8), 10.9 g (10 mol %) of the compound (M-9), 38.8 g (40 mol %) of the compound (M-10), and 19.6 g (20 mol %) of the compound (M-1) in 200 g of 2-butanone, and then adding thereto 3.59 g of AIBN. After a 1,000 mL three-necked flask charged with 100 g of 2-butanone was purged with nitrogen for 30 min, the liquid was heated to 80° C. while stirring, and thereto was added dropwise the prepared monomer solution using a dropping funnel over 3 hrs. The time when dropwise addition was started was assumed to be a start time point of the polymerization reaction, and the polymerization reaction was carried out for 6 hrs. After completion of the polymerization reaction, the polymerization solution was cooled with water to a temperature of no greater than 30° C. The cooled polymerization solution was charged into 2,000 g of methanol, and a white powder thus precipitated was filtered off. After the filtered white powder was washed with 400 g of methanol twice, filtration and drying at 50° C. for 17 hrs gave a white powdery polymer (A-1) (84.2 g; yield: 84%). The polymer (A-1) thus obtained had an Mw of 5,500, and the Mw/Mn of 1.42, with a proportion of residual low molecular components being 0.05%. In addition, as a result of the ¹³C-NMR analysis, a copolymer including a structural unit derived from the compound (M-8): a structural unit derived from the compound (M-9): a structural unit derived from the compound (M-10): a structural unit derived from the compound (M-1) at a ratio of 28.3:9.1:42.8:19.8 (mol %) was ascertained.

### Examples 9 to 15, and Synthesis Examples 1 to 2

Polymers (A-2) to (A-8) and (a-1) to (a-2) were obtained by a similar operation to Example 8 except that the monomers presented in Table 1 were blended in a given amount. In addition, the Mw, Mw/Mn and yield (%) of each resulting polymer, and the content of the structural unit derived from each monomer in each polymer are collectively shown in Table 1.

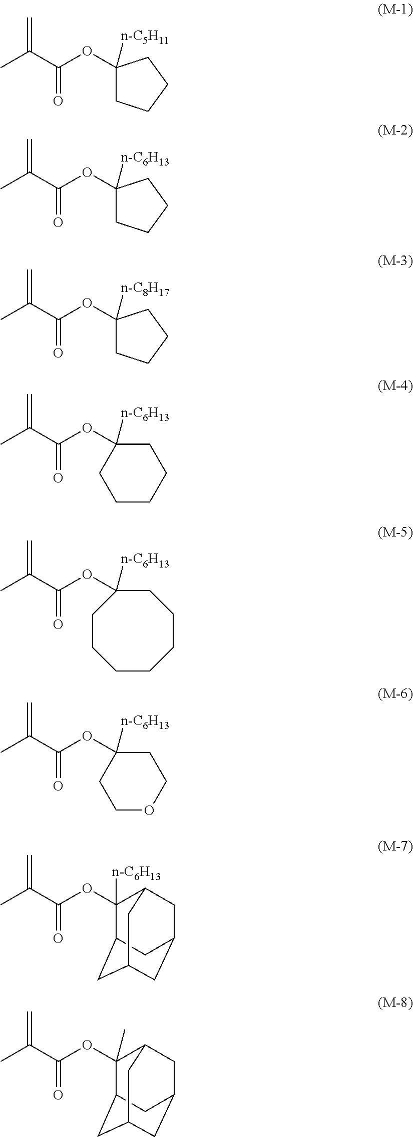

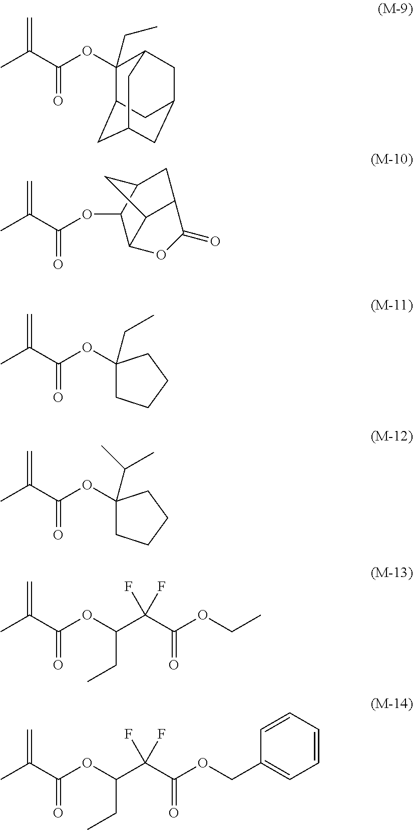

TABLE 1

| | | Amount of | | Structural | | |
|---|---|---|---|---|---|---|
| | | compound blended | | unit in the | | |
| | (A1) | | amount | polymer | Physical | |
| | Base | | blended | content | property value | |
| | polymer | compound | (mol %) | (mol %) | Mw | Mw/Mn |
| Example 8 | A-1 | M-1 | 20 | 19.8 | 5,500 | 1.42 |
| | | M-8 | 30 | 28.3 | | |
| | | M-9 | 10 | 9.1 | | |
| | | M-10 | 40 | 42.8 | | |
| Example 9 | A-2 | M-1 | 30 | 30.4 | 5,500 | 1.41 |
| | | M-8 | 30 | 29.2 | | |
| | | M-10 | 40 | 40.4 | | |
| Example 10 | A-3 | M-2 | 30 | 29.1 | 5,500 | 1.41 |
| | | M-8 | 30 | 26.5 | | |
| | | M-10 | 40 | 44.4 | | |
| Example 11 | A-4 | M-3 | 30 | 27.6 | 5,500 | 1.41 |
| | | M-8 | 30 | 30.8 | | |
| | | M-10 | 40 | 41.6 | | |
| Example 12 | A-5 | M-4 | 30 | 28.3 | 5,500 | 1.41 |
| | | M-8 | 30 | 30.6 | | |
| | | M-10 | 40 | 41.1 | | |
| Example 13 | A-6 | M-5 | 30 | 28.5 | 5,500 | 1.41 |
| | | M-8 | 30 | 30.1 | | |
| | | M-10 | 40 | 41.4 | | |
| Example 14 | A-7 | M-6 | 30 | 29.4 | 5,500 | 1.41 |
| | | M-8 | 30 | 31.2 | | |
| | | M-10 | 40 | 39.4 | | |
| Example 15 | A-8 | M-7 | 30 | 26.3 | 5,500 | 1.40 |
| | | M-8 | 30 | 31.5 | | |
| | | M-10 | 40 | 42.2 | | |
| Synthesis | a-1 | M-11 | 20 | 21.1 | 5,500 | 1.43 |
| Example 1 | | M-8 | 30 | 28.5 | | |
| | | M-9 | 10 | 8.8 | | |
| | | M-10 | 40 | 41.6 | | |
| Synthesis | a-2 | M-12 | 30 | 30.8 | 5,500 | 1.41 |
| Example 2 | | M-8 | 30 | 29.1 | | |
| | | M-10 | 40 | 40.1 | | |

### Synthesis of Polymer (A2-2)

### Synthesis Example 3

A monomer solution was prepared by dissolving 17.4 g (20 mol %) of the compound (M-11), and 83.6 g (80 mol %) of the compound (M-13) in 100 g of 2-butanone, and adding thereto 3.43 g of AIBN. After a 1,000 mL three-necked flask charged with 100 g of 2-butanone was purged with nitrogen for 30 min, the liquid was heated to 80° C. while stirring, and thereto was added dropwise the prepared monomer solution using a dropping funnel over 3 hrs. The time when dropwise addition was started was assumed to be a start time point of the polymerization reaction, and the polymerization reaction was carried out for 6 hrs. After completion of the polymerization reaction, the polymerization solution was cooled with water to a temperature of no greater than 30° C. The polymerization solution was concentrated in vacuo with an evaporator until the polymerize solution had a weight of 150 g. Thereafter, the concentrated liquid was charged into a mix liquid of 760 g of methanol and 40 g of water, whereby a white solid in a state of slime was precipitated. The liquid portion was removed by decantation, and the solid thus recovered was dried in vacuo at 60° C. for 15 hrs to obtain 61.3 g of a polymer (A2-2-1) (yield: 61%) as a white powder. The polymer (A2-2-1) had an Mw of 3,500, and the Mw/Mn of 1.66. In addition, as a result of the ¹³C-NMR analysis, a copolymer including a structural unit derived from the compound (M-11): a structural unit derived from the compound (M-13) at a ratio of 19.6:80.4 (mol %) was ascertained.

### Synthesis Example 4

A monomer solution was prepared by dissolving 14.6 g (20 mol %) of the compound (M-11), and 86.4 g (80 mol %) of the compound (M-14) in 100 g of 2-butanone, and adding thereto 2.84 g of AIBN. After a 1,000 mL three-necked flask charged with 100 g of 2-butanone was purged with nitrogen for 30 min, the liquid was heated to 80° C. while stirring, and thereto was added dropwise the prepared monomer solution using a dropping funnel over 3 hrs. The time when dropwise addition was started was assumed to be a start time point of the polymerization reaction, and the polymerization reaction was carried out for 6 hrs. After completion of the polymerization reaction, the polymerization solution was cooled with water to a temperature of no greater than 30° C. The polymerization solution was concentrated in vacuo with an evaporator until the polymerize solution had a weight of 150 g. Thereafter, the concentrated liquid was charged into a mix liquid of 760 g of methanol and 40 g of water, whereby a white solid in a state of slime was precipitated. The liquid portion was removed by decantation, and the solid thus recovered was dried in vacuo at 60° C. for 15 hrs to obtain 52.4 g of a polymer (A2-2-2) (yield: 52%) as a white powder. The polymer (A2-2-2) had an Mw of 3,500, and the Mw/Mn of 1.63. In addition, as a result of the ¹³C-NMR analysis, a copolymer including a structural unit derived from the compound (M-11): a structural unit derived from the compound (M-14) at a ratio of 20.3:79.7 (mol %) was ascertained.

### Preparation of Radiation-Sensitive Resin Composition

The acid generator (B), the acid diffusion control agent and the solvent used in preparing the radiation-sensitive resin composition are as shown in the following.

### (B) Acid Generator

A compound represented by the following formula (B-1)

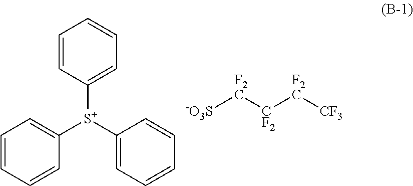

### Acid Diffusion Control Agent

A compound represented by the following formula (D-1)

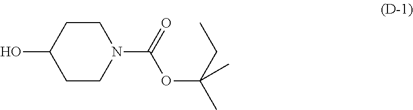

### Solvent

The solvents used in Examples and Comparative Examples are presented below.

(E-1) propylene glycol monomethyl ether acetate

(E-2) cyclohexanone

(E-3) γ-butyrolactone

### Example 16

A radiation-sensitive resin composition was prepared by mixing 100 parts by mass of the polymer (A-1) obtained in Example 8, 9.9 parts by mass of the acid generating agent (B-1), 5 parts by mass of the polymer (A2-2-1) obtained in Synthesis Example 3, 7.9 parts by mass of the acid diffusion control agent (D-1), and 2,590 parts by mass of the solvent (E-1), 1,110 parts by mass of the solvent (E-2) and 200 parts by mass of the solvent (E-3), and filtrating the resultant mix solution through a filter having a pore size of 0.20 μm.

### Examples 17 to 25, and Comparative Examples 1 to 2

Each radiation-sensitive resin composition was prepared by a similar operation to Example 16 except that the blend formulation was as shown in Table 2.

TABLE 2

| | (A1) Base | | (A2) Fluorine- | | (B) Acid | | | | | |
|---|---|---|---|---|---|---|---|---|---|---|
| | polymer | | containing polymer | | generator | | | | | |
| | | parts | | parts | | parts | Sensitivity | | DOF | Etching |
| | type | by mass | type | by mass | type | by mass | (mJ/cm²) | LWR | (nm) | resistance |
| Example 16 | A-1 | 100 | A2-2-1 | 5 | B-1 | 9.9 | 33.5 | favorable | 80 | favorable |
| Example 17 | A-2 | 100 | A2-2-2 | 5 | B-1 | 9.9 | 35.2 | favorable | 100 | favorable |
| Example 18 | A-1 | 100 | A2-2-2 | 5 | B-1 | 9.9 | 34.4 | favorable | 80 | favorable |
| Example 19 | A-2 | 100 | A2-2-1 | 5 | B-1 | 9.9 | 36.1 | favorable | 100 | favorable |
| Example 20 | A-3 | 100 | A2-2-1 | 5 | B-1 | 9.9 | 32.7 | favorable | 100 | favorable |
| Example 21 | A-4 | 100 | A2-2-1 | 5 | B-1 | 9.9 | 31.3 | favorable | 100 | favorable |
| Example 22 | A-5 | 100 | A2-2-1 | 5 | B-1 | 9.9 | 32.2 | favorable | 100 | favorable |
| Example 23 | A-6 | 100 | A2-2-1 | 5 | B-1 | 9.9 | 30.8 | favorable | 120 | favorable |
| Example 24 | A-7 | 100 | A2-2-1 | 5 | B-1 | 9.9 | 31.8 | favorable | 100 | favorable |
| Example 25 | A-8 | 100 | A2-2-1 | 5 | B-1 | 9.9 | 39.3 | favorable | 100 | favorable |
| Comparative | a-1 | 100 | A2-2-1 | 5 | B-1 | 9.9 | 42.2 | unfavorable | 40 | unfavorable |
| Example 1 | | | | | | | | | | |
| Comparative | a-2 | 100 | A2-2-1 | 5 | B-1 | 9.9 | 40.5 | unfavorable | 60 | unfavorable |
| Example 2 | | | | | | | | | | |

### Evaluations

### Evaluation of Sensitivity

On a 12-inch silicon wafer having an underlayer antireflective film (“ARC66”, manufactured by Nissan Chemical Industries, Ltd.) provided thereon, a coating film having a film thickness of 75 nm was provided by the radiation-sensitive resin composition, and thereafter subjected to soft baking (SB) at 100° C. for 60 sec. Next, the coating film was exposed using an ArF excimer laser immersion Scanner (“NSR S610C”, manufactured by NIKON Corporation) under a condition involving an NA of 1.3, a ratio of 0.800 and Annular through a mask pattern for formation of a pattern with 50 nm Line and 100 nm Pitch. After the exposure, post-baking (PEB) was carried out on each radiation-sensitive resin composition at 95° C. for 60 sec. Thereafter, the coating film was developed with a 2.38% by mass aqueous tetramethylammonium hydroxide solution and washed with water, followed by drying to form a positive type resist pattern. In accordance with this method, an exposure dose at which a line having a line width of 50 nm was formed on portions exposed through the mask pattern for formation of a pattern with 50 nm Line and 100 nm Pitch is defined as “optimum exposure dose” (Eop). The optimum exposure dose was determined as sensitivity (mJ/cm²). It is to be noted that a scanning electron microscope (“CG-4000”, Hitachi High-Technologies Corporation) was used for the measurement of the lengths. When the sensitivity was no greater than 40 (mJ/cm²), the evaluation was made as being “favorable”.

### Line Width Roughness (LWR)

A positive type resist pattern was formed according to a method similar to the method in the evaluation of sensitivity (mJ/cm²), whereby an optimum exposure dose (Eop) was determined. The line having a line width of 50 nm formed at the Eop was observed from above the pattern using a line-width measurement SEM “S9220” manufactured by Hitachi Corporation to determine the line width at ten arbitrary points. A value of 3-Sigma (variance) of the measurement of the line width was defined as LWR (nm). When the LWR was no greater than 5 nm, the formed pattern configuration was evaluated as being favorable.

### Depth of Focus (DOF)

With respect to the dimension of a pattern resolved through a mask for a 50 nm line and space pattern at the optimum exposure dose (Eop) in the evaluation of the sensitivity, the focus amplitude when the dimension falls within the range of ±10% of the designed dimension of the mask was defined as DOF (nm).

### Etching Resistance

On a silicon wafer having a diameter of 8 inch was coated each radiation-sensitive compositions of Examples and Comparative Examples by spin coating using CLEAN TRACK (Tokyo Electron Limited, “ACT12”), and a resist film having a film thickness of 0.3 μm was provided by heating on a hot plate at 100° C. for 60 sec. The resist film was subjected to an etching treatment using an etching system “EXAM” (manufactured by Shinko Seiki Co., Ltd.) with CF₄/Ar/O₂ (CF₄: 40 mL/min; Ar: 20 mL/min; O₂: 5 mL/min; pressure: 20 Pa; RF power: 200 W; treatment time period: 40 sec; and temperature: 15° C.). The film thicknesses before and after the etching treatment were measured to determine the etching rate. the evaluation was made as being: “favorable” when the etching rate was less than 170 nm/min; “somewhat favorable” when the etching rate was no less than 170 nm/min and no greater than 200 nm/min; and “unfavorable” when the etching rate was no less than 200 nm/min.

The results of evaluations are together shown in Table 2.

As shown in Table 2, it was revealed that the radiation-sensitive resin composition of the embodiment of the present invention was superior in all the sensitivity, lithography performances in terms of LWR and DOF, and etching resistance.

### 2. Type in which the Base Polymer (A1-2) and the Fluorine-Containing Polymer (A2-1) are Contained

### Synthesis of Fluorine-Containing Polymer (A2-1)

Monomers used for the synthesis of the fluorine-containing polymer (A2-1) and the base polymer (A1-2) are shown below.

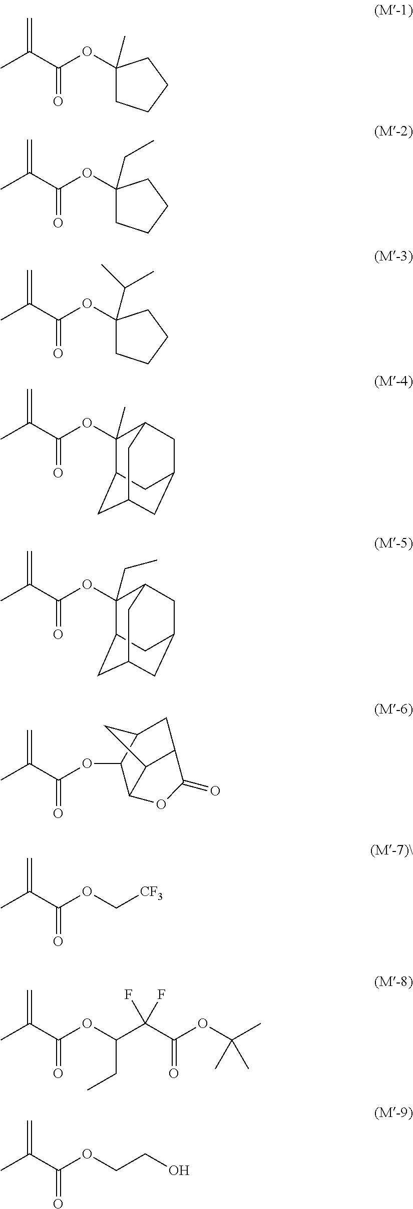

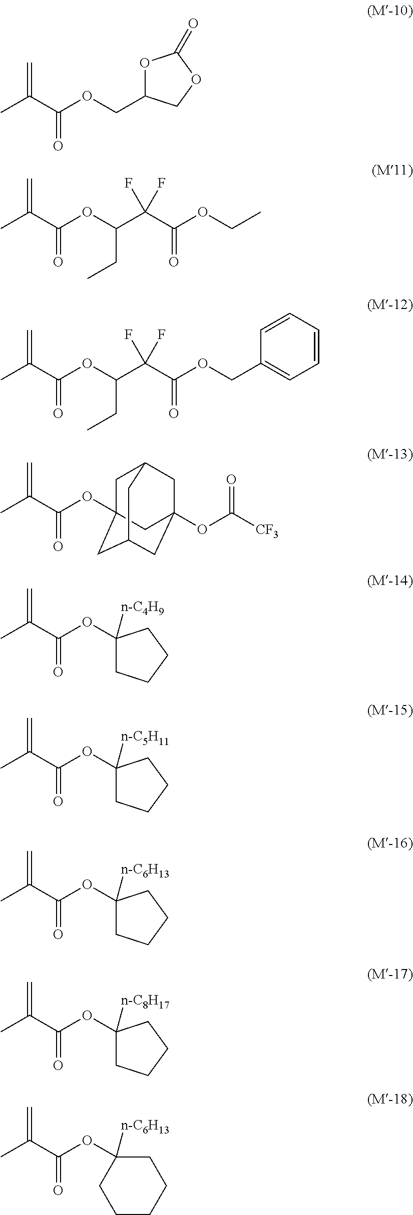

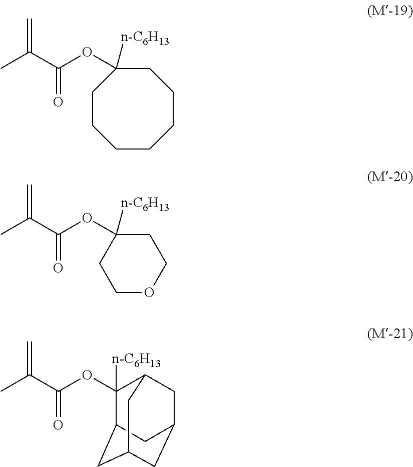

### Synthesis Example 5

A monomer solution was prepared by dissolving 18.3 g (20 mol %) of the compound (M′-15) and 81.7 g (80 mol %) of the compound (M′-11) in 200 g of 2-butanone, and then adding thereto 3.35 g of AIBN. After a 1,000 mL three-necked flask charged with 100 g of 2-butanone was purged with nitrogen for 30 min, the liquid was heated to 80° C. while stirring, and thereto was added dropwise the prepared monomer solution using a dropping funnel over 3 hrs. The time when dropwise addition was started was assumed to be a start time point of the polymerization reaction, and the polymerization reaction was carried out for 6 hrs. After completion of the polymerization reaction, the polymerization solution was cooled with water to a temperature of no greater than 30° C. The cooled polymerization solution was charged into 2,000 g of methanol, and a white powder thus precipitated was filtered off. After the filtered white powder was washed with 400 g of methanol twice, filtration and drying at 50° C. for 17 hrs gave a white powdery polymer (A′-1) (76.2 g; yield: 76%). The polymer (A′-1) thus obtained had an Mw of 3,500, and the Mw/Mn of 1.61. In addition, as a result of the ¹³C-NMR analysis, the ratio of a structural unit derived from the compound (M′-15): a structural unit derived from the compound (M′-11) was 19.9:80.1 (mol %).

### Synthesis Examples 6 to 18

Polymers (A′-2) to (A′-12), (a′-1) and (a′-2) were obtained by a similar operation to Synthesis Example 1 except that the monomers presented in Table 1 were blended in a given amount. In addition, the Mw and Mw/Mn of each resulting polymer, and the content of the structural unit derived from each monomer in each polymer are collectively shown in Table 3.

TABLE 3

| | | Amount of | | | | |
|---|---|---|---|---|---|---|
| | | monomer | | Structural | Physical | |
| | (A2) | blended | | unit in the | property | |
| | Fluorine- | | amount | polymer | value | |
| | containing | | blended | content | | Mw/ |
| | polymer | compound | mol % | mol % | Mw | Mn |
| Synthesis | A′-1 | M′-15 | 20 | 19.9 | 3,500 | 1.61 |
| Example 5 | | M′-11 | 80 | 80.1 | | |
| Synthesis | A′-2 | M′-16 | 20 | 17.1 | 3,500 | 1.60 |
| Example 6 | | M′-11 | 80 | 82.9 | | |
| Synthesis | A′-3 | M′-17 | 20 | 22.3 | 3,500 | 1.63 |
| Example 7 | | M′-11 | 80 | 77.7 | | |
| Synthesis | A′-4 | M′-18 | 20 | 21.5 | 3,500 | 1.61 |
| Example 8 | | M′-11 | 80 | 78.5 | | |
| Synthesis | A′-5 | M′-19 | 20 | 17.6 | 3,500 | 1.64 |
| Example 9 | | M′-11 | 80 | 82.4 | | |
| Synthesis | A′-6 | M′-20 | 20 | 22.4 | 3,500 | 1.61 |
| Example 10 | | M′-11 | 80 | 77.6 | | |
| Synthesis | A′-7 | M′-21 | 20 | 15.3 | 3,500 | 1.64 |
| Example 11 | | M′-11 | 80 | 84.7 | | |
| Synthesis | A′-8 | M′-16 | 10 | 9.9 | 3,500 | 1.60 |
| Example 12 | | M′-7 | 10 | 9.3 | | |
| | | M′-11 | 80 | 80.8 | | |
| Synthesis | A′-9 | M′-16 | 20 | 19.7 | 3,500 | 1.59 |
| Example 13 | | M′-8 | 80 | 80.3 | | |
| Synthesis | A′-10 | M′-16 | 20 | 19.9 | 3,500 | 1.61 |
| Example 14 | | M′-12 | 80 | 80.1 | | |
| Synthesis | A′-11 | M′-16 | 20 | 18.0 | 3,500 | 1.58 |
| Example 15 | | M′-13 | 80 | 82.0 | | |
| Synthesis | A′-12 | M′-16 | 10 | 8.0 | 4,000 | 1.64 |
| Example 16 | | M′-11 | 80 | 79.4 | | |
| | | M′-3 | 10 | 12.6 | | |
| Synthesis | a′-1 | M′-3 | 20 | 20.8 | 3,500 | 1.60 |
| Example 17 | | M′-11 | 80 | 79.2 | | |
| Synthesis | a′-2 | M′-14 | 20 | 17.6 | 3,500 | 1.62 |
| Example 18 | | M′-13 | 80 | 82.4 | | |

### Synthesis of Base Polymer (A1-2)

### Synthesis Example 19

A monomer solution was prepared by dissolving 34.7 g (40 mol %) of the compound (M′-1), 12.8 g (10 mol %) of the compound (M′-5), 45.8 g (40 mol %) of the compound (M′-6), and 6.7 g (10 mol %) of the compound (M′-9) in 200 g of 2-butanone, and adding thereto 4.23 g of AIBN. After a 1,000 mL three-necked flask charged with 100 g of 2-butanone was purged with nitrogen for 30 min, the liquid was heated to 80° C. while stirring, and thereto was added dropwise the prepared monomer solution using a dropping funnel over 3 hrs. The time when dropwise addition was started was assumed to be a start time point of the polymerization reaction, and the polymerization reaction was carried out for 6 hrs. After completion of the polymerization reaction, the polymerization solution was cooled with water to a temperature of no greater than 30° C. The cooled polymerization solution was charged into 2,000 g of methanol, and a white powder thus precipitated was filtered off. After the filtered white powder was washed with 400 g of methanol twice, filtration and drying at 50° C. for 17 hrs gave a white powdery polymer (A1-2-1) (81.6 g; yield: 82%). The polymer (A1-2-1) thus obtained had an Mw of 5,500, and the Mw/Mn of 1.41. In addition, as a result of the ¹³C-NMR analysis, the ratio of a structural unit derived from the compound (M′-1): a structural unit derived from the compound (M′-5): a structural unit derived from the compound (M′-6): a structural unit derived from the compound (M′-9) was 39.8: 8.6:40.5:11.1 (mol %).

### Synthesis Examples 20 to 23

Polymers (A1-2-2) to (A1-2-5) were obtained by a similar operation to Synthesis Example 19 except that the monomers presented in Table 4 were blended in a given amount. In addition, the Mw and Mw/Mn of each resulting polymer, and the content of the structural unit derived from each monomer in each polymer are collectively shown in Table 4.

TABLE 4

| | | Amount of | | Structural | | |
|---|---|---|---|---|---|---|
| | | monomer blended | | unit in the | | |
| | (A1) | | amount | polymer | Physical | |
| | Base | | blended | content | property value | |
| | polymer | compound | mol % | mol % | Mw | Mw/Mn |
| Synthesis | A1-2-1 | M′-1 | 40 | 39.8 | 5,500 | 1.41 |
| Example 19 | | M′-5 | 10 | 8.6 | | |
| | | M′-6 | 40 | 40.5 | | |
| | | M′-9 | 10 | 11.1 | | |
| Synthesis | A1-2-2 | M′-2 | 20 | 21.1 | 5,500 | 1.43 |
| Example 20 | | M′-4 | 30 | 28.5 | | |
| | | M′-5 | 10 | 8.8 | | |
| | | M′-6 | 40 | 41.6 | | |
| Synthesis | A1-2-3 | M′-3 | 30 | 30.8 | 5,500 | 1.41 |
| Example 21 | | M′-4 | 30 | 29.1 | | |
| | | M′-6 | 40 | 40.1 | | |
| Synthesis | A1-2-4 | M′-1 | 30 | 30.5 | 6,000 | 1.39 |
| Example 22 | | M′-4 | 10 | 9.5 | | |
| | | M′-5 | 10 | 8.8 | | |
| | | M′-6 | 30 | 31.1 | | |
| | | M′-10 | 20 | 20.1 | | |
| Synthesis | A1-2-5 | M′-3 | 35 | 34.5 | 6,000 | 1.42 |
| Example 23 | | M′-6 | 45 | 44.9 | | |
| | | M′-9 | 10 | 11.2 | | |
| | | M′-8 | 10 | 9.4 | | |

### Preparation of Radiation-Sensitive Resin Composition

The acid generator (B), the acid diffusion control agent and the solvent used in preparing the radiation-sensitive resin composition are as shown in the following.

### (B) Acid Generator

A compound represented by the following formula (B-1)

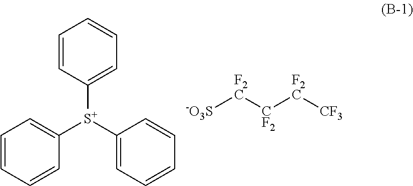

### Acid Diffusion Control Agent

A compound represented by the following formula (D-1)

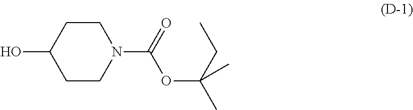

### Solvent

The solvents used in Examples and Comparative Examples are presented below.

(E′-1) propylene glycol monomethyl ether acetate

(E′-2) cyclohexanone

(E′-3) γ-butyrolactone

### Example 26

A radiation-sensitive resin composition was prepared by mixing 5 parts by mass of the polymer (A′-1) obtained in Synthesis Example 5, 9.9 parts by mass of the acid generator (B′-1), 100 parts by mass of the polymer (A1-2-1) obtained in Synthesis Example 19, 7.9 parts by mass of the acid diffusion control agent (D′-1), and 2,590 parts by mass of the solvent (E′-1), 1,110 parts by mass of the solvent (E′-2) and 200 parts by mass of the solvent (E′-3), and filtrating the resultant mix solution through a filter having a pore size of 0.20 μm.

### Examples 27 to 41, and Comparative Examples 3 to 4

Each radiation-sensitive resin composition was prepared by a similar operation to Example 26 except that the blend formulation was as shown in Table 5.

TABLE 5

| | (A2) Fluorine- | | (A1) Base | | (B) Acid | | | | | |
|---|---|---|---|---|---|---|---|---|---|---|
| | containing polymer | | polymer | | generator | | Pattern | | | Bridge defect- |
| | | parts by | | parts by | | parts by | formation | | Generation | preventing |
| | type | mass | type | mass | type | mass | property | LWR | of scum | performance |
| Example 26 | A′-1 | 5 | A1-2-1 | 100 | B-1 | 9.9 | favorable | favorable | not found | favorable |
| Example 27 | A′-2 | 5 | A1-2-1 | 100 | B-1 | 9.9 | favorable | favorable | not found | favorable |
| Example 28 | A′-3 | 5 | A1-2-1 | 100 | B-1 | 9.9 | favorable | favorable | not found | favorable |
| Example 29 | A′-4 | 5 | A1-2-1 | 100 | B-1 | 9.9 | favorable | favorable | not found | favorable |
| Example 30 | A′-5 | 5 | A1-2-1 | 100 | B-1 | 9.9 | favorable | favorable | not found | favorable |
| Example 31 | A′-6 | 5 | A1-2-1 | 100 | B-1 | 9.9 | favorable | favorable | not found | favorable |
| Example 32 | A′-7 | 5 | A1-2-1 | 100 | B-1 | 9.9 | favorable | favorable | not found | favorable |
| Example 33 | A′-8 | 3 | A1-2-1 | 100 | B-1 | 9.9 | favorable | favorable | not found | somewhat |
| | | | | | | | | | | favorable |
| Example 34 | A′-9 | 3 | A1-2-1 | 100 | B-1 | 9.9 | favorable | favorable | not found | somewhat |
| | | | | | | | | | | favorable |
| Example 35 | A′-10 | 3 | A1-2-1 | 100 | B-1 | 9.9 | favorable | favorable | not found | favorable |
| Example 36 | A′-11 | 3 | A1-2-1 | 100 | B-1 | 9.9 | favorable | favorable | not found | favorable |
| Example 37 | A′-12 | 5 | A1-2-1 | 100 | B-1 | 9.9 | favorable | favorable | not found | favorable |
| Example 38 | A′-2 | 5 | A1-2-2 | 100 | B-1 | 9.9 | favorable | favorable | not found | favorable |
| Example 39 | A′-2 | 5 | A1-2-3 | 100 | B-1 | 9.9 | favorable | favorable | not found | favorable |
| Example 40 | A′-2 | 5 | A1-2-4 | 100 | B-1 | 9.9 | favorable | favorable | not found | favorable |
| Example 41 | A′-2 | 5 | A1-2-5 | 100 | B-1 | 9.9 | favorable | favorable | not found | favorable |
| Comparative | a′-1 | 5 | A1-2-1 | 100 | B-1 | 9.9 | unfavorable | unfavorable | found | unfavorable |
| Example 3 | | | | | | | | | | |
| Comparative | a′-2 | 5 | A1-2-1 | 100 | B-1 | 9.9 | unfavorable | unfavorable | found | unfavorable |
| Example 4 | | | | | | | | | | |

### Evaluations

The results of the following evaluations are shown in Table 5.

### Pattern Formation Property

On a 12-inch silicon wafer which had been provided with an underlayer antireflective film thereon using an antireflective coating material for semiconductors (trade name “ARC66”, manufactured by Nissan Chemical Industries, Ltd.), a coating film having a film thickness of 110 nm was provided using the radiation-sensitive resin composition prepared as described above, and thereafter subjected to soft baking (SB) at 120° C. for 60 sec. Next, the coating film was exposed using an ArF excimer laser immersion Scanner (trade name “NSR S610C”, manufactured by NIKON Corporation) under a condition involving NA of 1.3, iNA of 1.27, a ratio of 0.800, Dipole X open Angle of 35 deg., through a mask pattern of line-and-space (1L 1S) with a target size of a width being 45 nm. After the exposure, PEB was carried out at 95° C. for 60 sec. Thereafter, the coating film was developed with a 2.38% by mass aqueous tetramethylammonium hydroxide solution as a developer solution using a developer, CLEAN TRACK (trade name: “LITHIUS Pro-i” manufactured by Tokyo Electron Limited), by way of a GP nozzle for 10 sec, followed by washing with water for 15 sec and drying to form a positive type resist pattern. In accordance with this method, an exposure dose at which line-and-space having a width of 45 nm was formed is defined as “optimum exposure dose”. A cross-sectional shape of the pattern formed at the optimum exposure dose was observed under a scanning electron microscope (trade name: “S-4800”, manufactured by Hitachi High-Technologies Corporation). With to the pattern 2 formed on the substrate 1 in FIG. 1, the line width at the top was designated as L1, and the line width at the bottom was designated as L2. The evaluation was made as being: “favorable” when the value “(L1−L2)/L1” fell within the range of from −0.15 to +0.15; and “unfavorable” when the value “(L1−L2)/L1” was less than −0.15, or greater than +0.15.

### Line Width Roughness (LWR)

A positive type resist pattern was formed similarly to the evaluation of the “Pattern Formation Property”. A pattern resolved at the optimum exposure dose using a scanning electron microscope (“CG4000”, manufactured by Hitachi High-Technologies Corporation) was observed from above, and the line width was measured at ten arbitrary points and 36 (variance) of the measurements was defined as LWR (unit: nm). The evaluation of a preventing property of LWR was made as being: “favorable” when the value of LWR was no greater than 5.0 nm; and “unfavorable” when the value of LWR exceeded 5.0 nm.

### Preventing Property of Scum

In the observation under a scanning electron microscope for the evaluation of “Pattern Formation Property”, the preventing property of scum was evaluated as being: “found” of “Generation of scum” when generation of undissolved matter was observed at light-exposed sites; and “not found” when undissolved matter was not observed.

### Bridge Defect-Preventing Performance

Exposure was carried out in a similar manner to the evaluation on “pattern formation property” using a line-and-space pattern (1L 1S) with a target size of a line width being 45 nm as a mask. In addition, in accordance with this method, an exposure dose at which line-and-space having a width of 45 nm was formed is defined as “optimum exposure dose”. It is to be noted that a scanning electron microscope (“S-9380”, manufactured by Hitachi High-Technologies Corporation) was used for the measurement of the line-width measurement. Thereafter, a defect performance on the line-and-space pattern (1L 1S) having a line width of 100 nm was determined using a defect inspection system (trade name: “KLA2810”, manufactured by KLA-Tencor Corporation). Then the defect determined by “KLA2810” was observed using a scanning electron microscope (“S-9380”, manufactured by Hitachi High-Technologies Corporation), and the number of bridge defects was counted to evaluate the bridge defect-preventing performance. The evaluation of the bridge defect-preventing performance was made as being: “favorable” when the number of detected bridge defects was less than 50; “somewhat favorable” when the number was no less than 50 and no greater than 100; and “unfavorable” when the number exceeded 100.

As is seen from Table 5, it was revealed that the radiation-sensitive resin composition of the embodiment of the present invention was superior in pattern formation properties and LWR performances, was capable of suppressing generation of scums, and had excellent bridge defect-preventing performances.

The radiation-sensitive resin composition of the embodiment of the present invention can be suitably used in forming a resist pattern in lithography processes of various types of electronic devices such as semiconductor devices and liquid crystal devices.

Obviously, numerous modifications and variations of the present invention are possible in light of the above teachings. It is therefore to be understood that within the scope of the appended claims, the invention may be practiced otherwise than as specifically described herein.

1. A radiation-sensitive resin composition comprising:
a polymer component that includes one or more types of polymers; and
a radiation-sensitive acid generator, wherein
at least one type of the polymer of the polymer component comprises a first structural unit represented by a following formula (1): 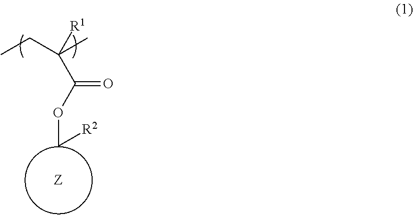
wherein, in the formula (1), R¹ represents a hydrogen atom, a fluorine atom, a methyl group or a trifluoromethyl group; R² represents a linear alkyl group having 5 to 21 carbon atoms; and Z represents a divalent alicyclic hydrocarbon group or an aliphatic heterocyclic group having a ring skeleton which has 4 to 20 atoms, wherein a part or all of hydrogen atoms included in the alicyclic hydrocarbon group and the aliphatic heterocyclic group represented by Z are not substituted or substituted.

2. The radiation-sensitive resin composition according to claim 1, wherein Z in the formula (1) represents a monocyclic group.

3. The radiation-sensitive resin composition according to claim 2, wherein Z in the formula (1) represents a divalent alicyclic hydrocarbon group having 5 or more and 8 or less atoms of the ring skeleton.

4. The radiation-sensitive resin composition according to claim 1, wherein R² in the formula (1) has 5 or more and 8 or less carbon atoms.

5. The radiation-sensitive resin composition according to claim 1, wherein the polymer component comprises:
a base polymer; and
a fluorine-containing polymer having a content of fluorine atoms higher than a content of the base polymer.

6. The radiation-sensitive resin composition according to claim 5, wherein the base polymer has the first structural unit.

7. The radiation-sensitive resin composition according to claim 5, wherein the fluorine-containing polymer has the first structural unit.

8. The radiation-sensitive resin composition according to claim 5, wherein the base polymer has a second structural unit represented by a formula (3): 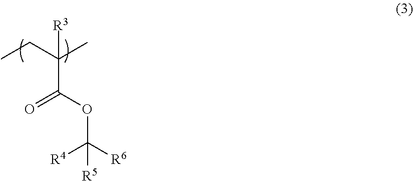
wherein, in the formula (3), R³ represents a hydrogen atom or a methyl group; R⁴ to R⁶ each independently represent an alkyl group having 1 to 4 carbon atoms or an alicyclic hydrocarbon group having 4 to 20 carbon atoms, or R⁴ represents an alkyl group having 1 to 4 carbon atoms or an alicyclic hydrocarbon group having 4 to 20 carbon atoms, and R⁵ and R⁶ taken together represent a divalent alicyclic hydrocarbon group having 4 to 20 carbon atoms together with the carbon atom to which R⁵ and R⁶ bond.

9. The radiation-sensitive resin composition according to claim 5, wherein the fluorine-containing polymer includes a third structural unit having a fluorine atom.

10. A pattern-forming method comprising:
providing a resist film on a substrate using the radiation-sensitive resin composition according to claim 1;
irradiating at least a part of the resist film with a radioactive ray to permit exposure;
heating the exposed resist film; and
developing the heated resist film.

11. The pattern-forming method according to claim 10, wherein the exposed resist film is heated at a heating temperature of less than 100° C.

12. A polymer comprising a structural unit represented by a formula (1): 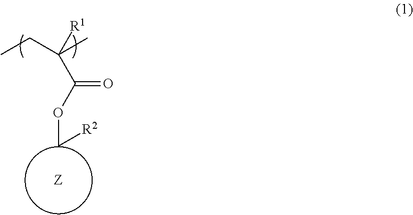
wherein, in the formula (1), R¹ represents a hydrogen atom, a fluorine atom, a methyl group or a trifluoromethyl group; R² represents a linear alkyl group having 5 to 21 carbon atoms; and Z represents a divalent alicyclic hydrocarbon group or an aliphatic heterocyclic group having a ring skeleton which has 4 to 20 atoms, wherein a part or all of hydrogen atoms included in the alicyclic hydrocarbon group and the aliphatic heterocyclic group represented by Z are not substituted or substituted.

13. A compound represented by a formula (2): 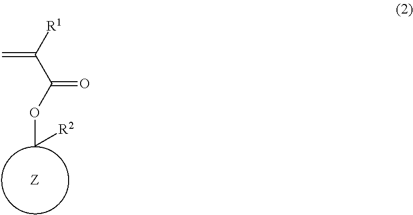
wherein, in the formula (2), R¹ represents a hydrogen atom, a fluorine atom, a methyl group or a trifluoromethyl group; R² represents a linear alkyl group having 5 to 21 carbon atoms; and Z represents a divalent alicyclic hydrocarbon group or an aliphatic heterocyclic group having a ring skeleton which has 4 to 20 atoms, wherein a part or all of hydrogen atoms included in the alicyclic hydrocarbon group and the aliphatic heterocyclic group represented by Z are not substituted or substituted.
